(19) United States
(12) Patent Application Publication
(10) Pub. No.: US 2025/0386481 A1
(43) Pub. Date: Dec. 18, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventor: Jhon Jhy LIAW, Hsinchu County (TW)

(73) Assignee: Taiwan Semiconductor Manufacturing Company, Ltd., Hsinchu (TW)

(21) Appl. No.: 18/746,338

(22) Filed: Jun. 18, 2024

(51) Int. Cl. H10B 10/00

(52) U.S. Cl. CPC H10B 10/125

(57) ABSTRACT

A method includes forming a first static random access memory (SRAM) cell over a semiconductive substrate, the first SRAM cell comprising a first write port and a first read port; forming a second SRAM cell over the semiconductive substrate and adjacent to the first SRAM cell, the second SRAM cell comprising a second write port and a second read port; forming a first metal layer over the semiconductive substrate, the first metal layer comprising a read bit-line, wherein the first and second SRAM cell share the read bit-line; forming a second metal layer over the first metal layer, the second metal layer comprising a write bit-line and a write bit-line bar, wherein the first and second SRAM cell share the write bit-line and the write bit-line bar.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a static random access memory (SRAM) cell in accordance with some embodiments of the present disclosure.

FIG. 2 illustrates a block diagram of an array of two-port SRAM cells in accordance with some embodiments of the present disclosure.

FIGS. 3A-3D illustrate cell array layout diagrams of a two-port SRAM circuit in accordance with some embodiments of the present disclosure.

FIG. 4 illustrates a perspective view of an example nano-FET device in accordance with some embodiments of the present disclosure.

FIGS. 5A-5C illustrate schematic cross-sectional views obtained from reference cross-section C1-C1′, C2-C2′, and C3-C3′ in FIG. 3A, respectively.

FIGS. 6A-17C illustrate schematic views of intermediate stages in the formation of a semiconductor structure in accordance with some embodiments.

FIG. 18A illustrates a cell array layout diagram of a two-port SRAM circuit in accordance with some embodiments of the present disclosure.

FIGS. 18B and 18C illustrate a power supply voltage line landing pad at M1 level and an underlying interconnect via in FIG. 18A in accordance with some embodiments of the present disclosure.

FIGS. 19A and 19B illustrate cell array layout diagrams of a two-port SRAM circuit in accordance with some embodiments of the present disclosure.

FIG. 20 illustrates a schematic view of a semiconductor structure in accordance with some embodiments of the present disclosure.

FIG. 21A is a schematic diagram of an electronic design automation (EDA) system in accordance with some embodiments of the present disclosure.

FIG. 21B is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, static random access memory (SRAM) bit-lines may dispose in lowest level metallization layer (M1) for bit-line capacitance reduction. However, when metal thickness and line width are continuous shrunk, the lowest level metal may push the metal pitch to limitation for logic circuit routing density improvement, which in turn induces high resistance issue in both SRAM bit-line and Vss conductors (IR drop concern), and therefore impact the cell speed and V_min performance.

Therefore, the present disclosure in various embodiments provides a metal line routing method to improve the functional density and operation performance on the IC structure. In the architecture of two-port SRAM cells, each cell can be designed with a distinct arrangement for its read and write pathways, utilizing a read bit-line along with a write bit-line and a write bit-line bar in two separate metallization layers for improved performance. When two adjacent two-port SRAM cells are grouped together in alignment with the word-line routing direction, they collectively can utilize a single read bit-line and a single pair of write bit-lines, allowing for a compact and efficient layout, supporting the operation of 16 transistors across 5 active regions. In some embodiments, the write pull-up transistors can be enhanced with a dielectric gate structure (e.g., common poly on diffusion edge (CPODE)) situated nearby to optimize their function. Furthermore, continuous gate end dielectric lines can incorporate at the two outer edges of the grouped cells adjacent to the write pull-up transistors. The gate end dielectric lines can extend across the entire height of the cell, functioning as a barrier to delineate the gate structures along the bit-line routing direction.

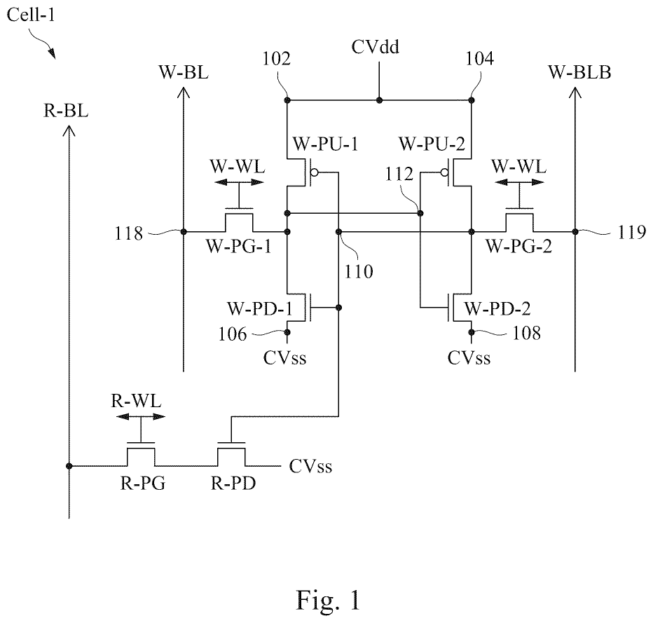

Reference is made to FIG. 1. FIG. 1 is a circuit diagram of a static random access memory (SRAM) cell in accordance with some embodiments of the present disclosure. Specifically, FIG. 1 illustrates a circuit diagram of a two-port eight-transistor (8T) SRAM cell Cell-1 in accordance with some embodiments. The SRAM cell Cell-1 can include a write port and a read port. In some embodiments, in the realm of deep sub-micron technology, the embedded SRAM cell (e.g., SRAM cell Cell-1) can have emerge as a storage component in high-speed communication, image processing, and system on chip (SoC) products. The two-port SRAM cell Cell-1 can facilitate parallel operations (including 1 read and 1 write operation within a single cycle), thereby delivering higher bandwidth compared to single-port SRAM cell. As shown in FIG. 1, the write port can include pull-up transistors W-PU-1 and W-PU-2, which may be P-type Metal-Oxide-Semiconductor (PMOS) transistors, and pull-down transistors W-PD-1 and W-PD-2 and pass-gate transistors W-PG-1 and W-PG-2, which may be N-type Metal-Oxide-Semiconductor (NMOS) transistors. In some embodiments, the pull-up transistor W-PU-1 and W-PU-2 may be NMOS transistors, and the pull-down transistors W-PD-1 and W-PD-2 and pass-gate transistors W-PG-1 and W-PG-2 may be PMOS transistors.

The gates of pass-gate transistors W-PG-1 and W-PG-2 are controlled by write word-line W-WL that determines whether SRAM cell Cell-1 is selected for writing into or not. A latch formed of pull-up transistors W-PU-1 and W-PU-2 and pull-down transistors W-PD-1 and W-PD-2 stores a bit, wherein the complementary values of the bit are stored in Storage Data (SD) node 110 and SD node 112. The stored bit can be written into SRAM cell Cell-1 through complementary bit-lines including write bit-line W-BL and write bit-line-bar W-BLB. SRAM cell Cell-1 is powered through a positive power supply node CVdd that has a positive power supply voltage (also denoted as VDD). The SRAM cell Cell-1 is also connected to power supply voltage CVss (also denoted as VSS), which may be an electrical ground. The transistors W-PU-1 and W-PD-1 form a first inverter. The transistors W-PU-2 and W-PD-2 form a second inverter. The input of the first inverter is connected to transistor W-PG-1 and the output of the second inverter. The output of the first inverter is connected to transistor W-PG-2 and the input of the second inverter.

The sources of pull-up transistors W-PU-1 and W-PU-2 are connected to the power supply nodes 102 and 104, respectively, which are further connected to power supply voltage (and line) CVdd. The sources of pull-down transistors W-PD-1 and W-PD-2 are connected to power supply voltage nodes 106 and 108, respectively, which are further connected to power supply voltage/line CVss. The gates of transistors W-PU-1 and W-PD-1 are connected to the drains of transistors W-PU-2 and W-PD-2, which form a connection node that is referred to as a date node 110. The gates of transistors W-PU-2 and W-PD-2 are connected to the drains of transistors W-PU-1 and W-PD-1, which connection node is referred to as a data node 112. A source/drain region of pass-gate transistor W-PG-1 is connected to write bit-line W-BL at a write bit-line node 118. A source/drain region of pass-gate transistor W-PG-2 is connected to a write bit-line-bar W-BLB at a write bit-line-bar node 119.

The SRAM cell Cell-1 further includes a read port, which includes read pull-down transistor R-PD and read pass-gate transistor R-PG connected in series. The gate of transistor R-PD is connected to the data node 112. The gate of transistor R-PG is connected to a read word-line R-WL. A source/drain region of transistor R-PG is connected to a read bit-line R-BL, which is connected to a local sensing circuit. A source/drain region of the transistor R-PD is connected to the power supply voltage/line.

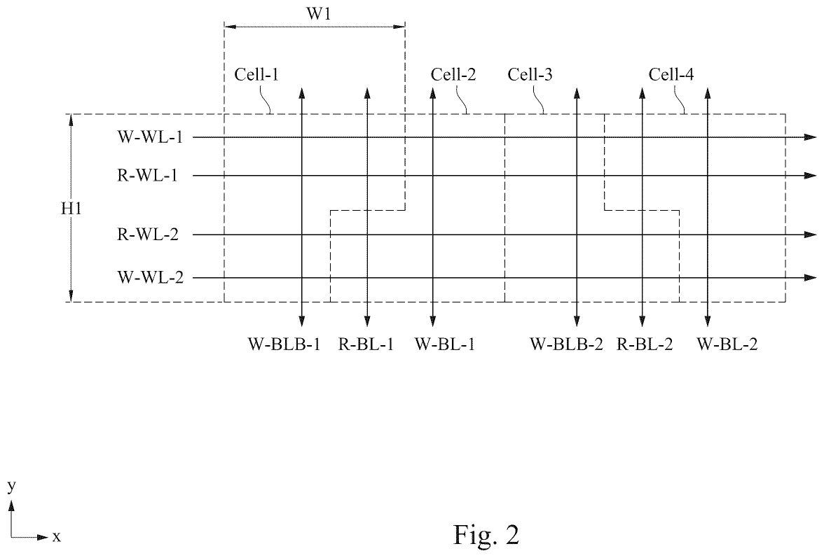

Reference is made to FIG. 2. FIG. 2 illustrates a block diagram of an array of two-port SRAM cells Cell-1, Cell-2, Cell-3, and Cell-4 in accordance with some embodiments of the present disclosure. The outer boundary of each of the SRAM cells Cell-1, Cell-2, Cell-3, and Cell-4 is illustrated using dashed lines. Each of the SRAM cells Cell-1, Cell-2, Cell-3, and Cell-4 has a non-rectangular shape or a non-square shape. The SRAM cell Cell-1, Cell-2, Cell-3, and Cell-4 have substantially the same configuration as each other. Specifically, the SRAM cell Cell-1, Cell-2, Cell-3, or Cell-4 may have an L-shaped profile defined by the dashed lines. In some embodiments, the SRAM cells Cell-1, Cell-2, Cell-3, and Cell-4 may have the same cell height H1. In some embodiments, the SRAM cells Cell-1, Cell-2, Cell-3, and Cell-4 may have the same cell width W1. Therefore, the SRAM cell Cell-2/Cell-4 may repeat reference numerals and/or letters as the SRAM cell Cell-1/Cell-3. The difference between the SRAM cells Cell-1 and Cell-2 is that the SRAM cell Cell-2 has a different orientation than the SRAM cell Cell-1, and the difference between the SRAM cells Cell-3 and Cell-4 is that the SRAM cell Cell-4 has a different orientation than the SRAM cell Cell-3. Specifically, the layout diagram of the SRAM cell Cell-2 is the layout diagram of the SRAM cells Cell-1 rotated 180 degrees, and the layout diagram of the SRAM cell Cell-4 is the layout diagram of the SRAM cells Cell-3 rotated 180 degrees.

As shown in FIG. 2, the two-port SRAM cells Cell-1, Cell-2, Cell-3, and Cell-4 can be aligned adjacently along the X-direction. The configuration of the bit-lines and word-lines with respect to these cells can be organized to optimize the SRAM cell array's functionality and efficiency. Specifically, the bit-lines (e.g., the read bit-line R-BL, the write bit-line W-BL, and the write bit-line-bar W-BLB) extend along the Y-direction. The word-lines (e.g., the write word-line W-WL and the read word-line R-WL) extend along the X-direction, mirroring the arrangement of the SRAM cells themselves.

Each pair of horizontally adjacent cells can share the same set of bit-lines through interconnection structure. For example, the two-port SRAM cells Cell-1 and Cell-2 can share the read bit-line R-BL-1, the write bit-line W-BL-1, and the write bit-line-bar W-BLB-1 for their operations. Similarly, the two-port SRAM cells Cell-3 and Cell-4 can share the read bit-line R-BL-2, the write bit-line W-BL-2, and the write bit-line-bar W-BLB-2 for their operations. From a top-down perspective view, the read bit-lines R-BL-1 and R-BL-2 can be positioned between the write bit-line and the write bit-line-bar for both cell pairs. Notably, the read bit-line R-BL may be situated on a different metal layer than the write bit-line W-BL and the write bit-line-bar W-BLB, offering flexibility in the design to accommodate various architectural requirements.

Additionally, every two two-port SRAM cells that are indirectly adjacent along the X-direction can share the same word-lines through interconnection structure. For example, the two-port SRAM cells Cell-1 and Cell-3 can share the write word-line W-WL-1 and read word-line R-WL-1 for their operations. Similarly, the two-port SRAM cells Cell-2 and Cell-4 can share the write word-line W-WL-2 and read word-line R-WL-2 for their operations. From a top-down perspective view, the read word-lines R-WL-1 and R-WL-2 can be positioned centrally between the write word-lines W-WL-1 and W-WL-2, offering a streamlined and efficient routing of signals. Moreover, similar to the bit-lines, the read word-line R-WL can be situated on a different metal layer than the write word-line W-WL, offering flexibility in the design to accommodate various architectural requirements.

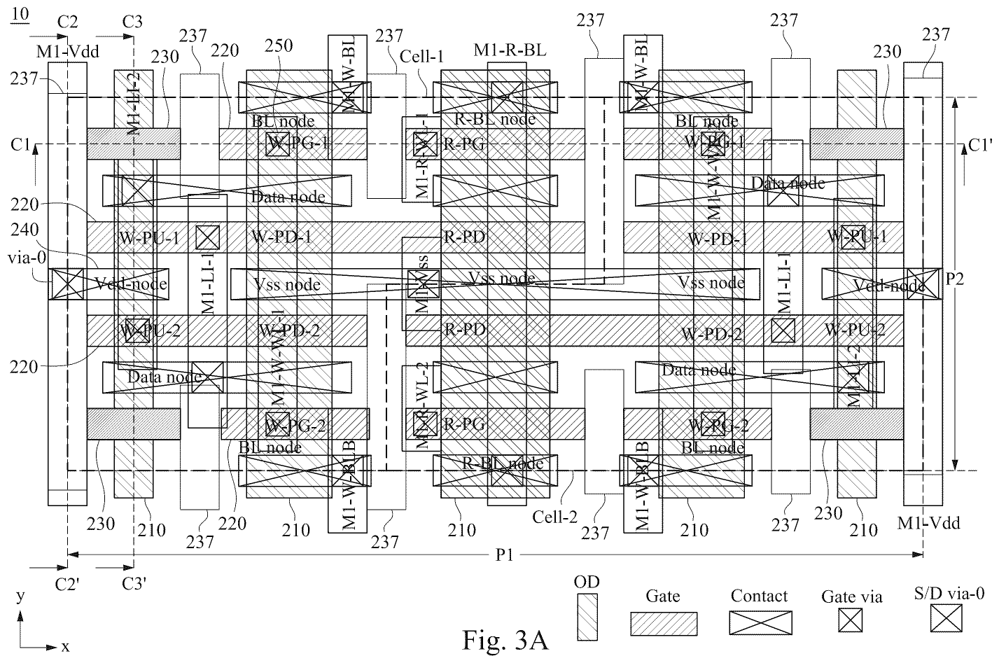

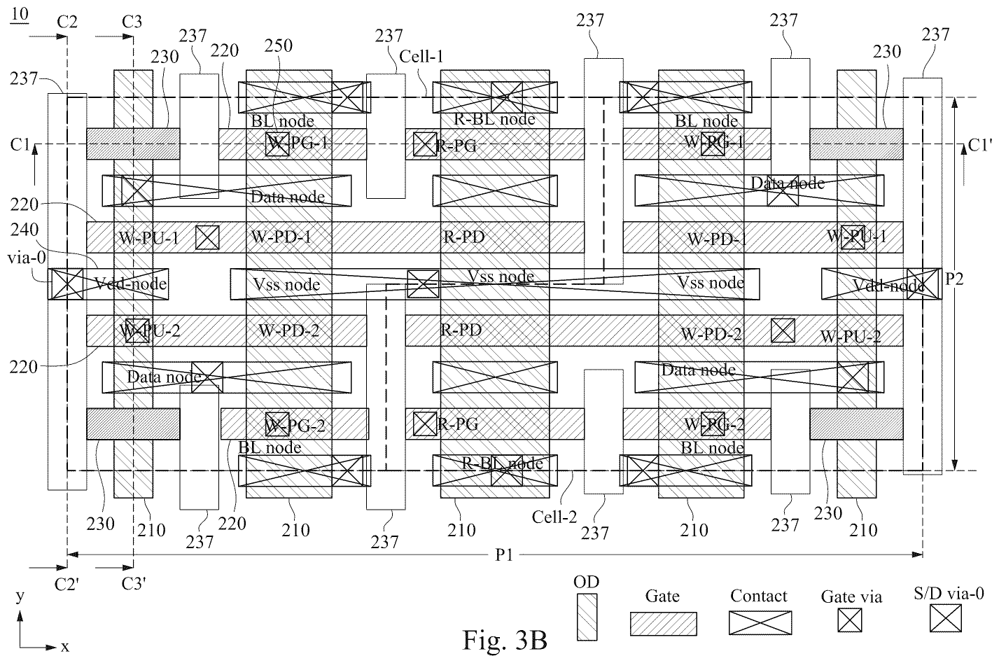

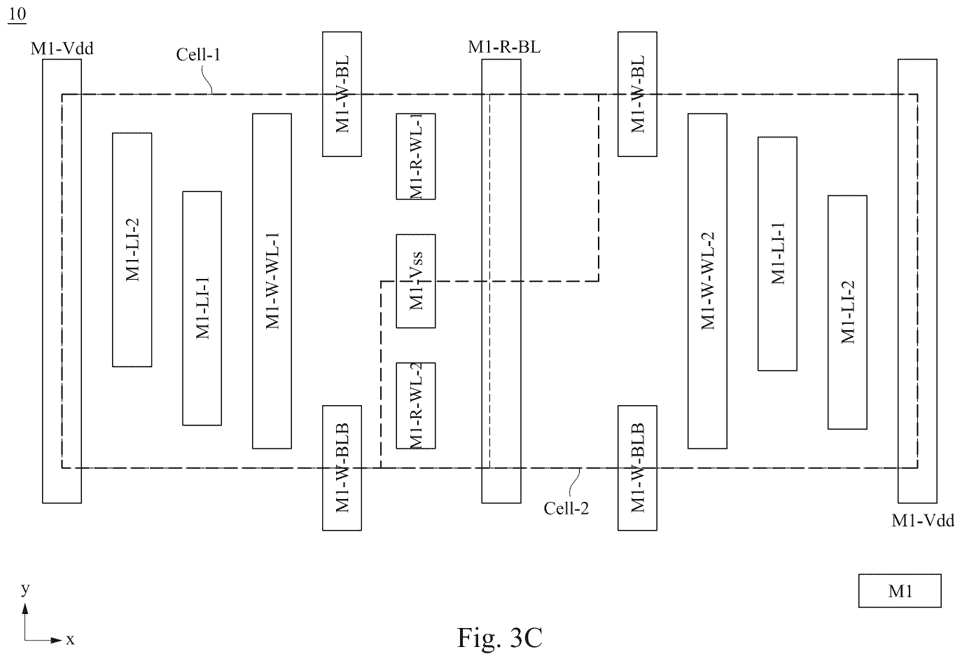

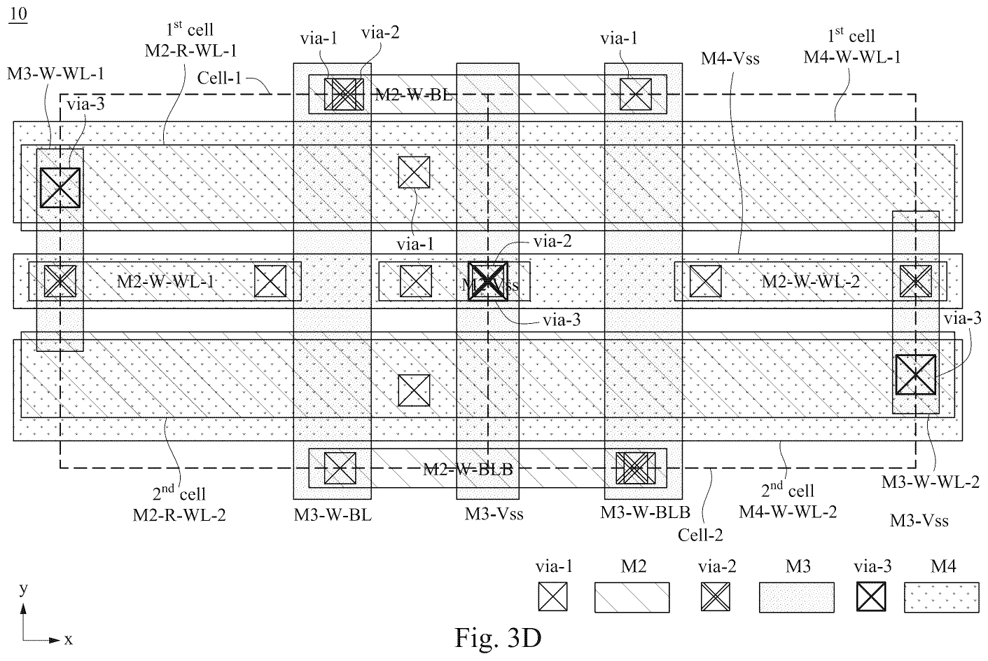

Reference is made to FIGS. 3A-3D. FIGS. 3A-3D illustrate cell array layout diagrams of two-port SRAM cells Cell-1 and Cell-2 of a circuit in accordance with some embodiments of the present disclosure. Specifically, FIG. 3A illustrates a cell array layout diagram of two-port SRAM cells Cell-1 and Cell-2 below a second interconnection layer (e.g., second metal layer) of the semiconductor structure 10. FIG. 3B illustrates a cell array layout diagram of two-port SRAM cells Cell-1 and Cell-2 below a first interconnection layer (e.g., first metal layer M1) of the semiconductor structure 10. FIG. 3C illustrates a cell array layout diagram of a first interconnection layer (e.g., first metal layer M1) in the two-port SRAM cells Cell-1 and Cell-2. FIG. 3D illustrates a cell array layout diagram of two-port SRAM cells Cell-1 and Cell-2 from a first interconnection layer (e.g., first metal layer M1) to a fourth interconnection layer (e.g., first metal layer M4) of the semiconductor structure 10.

In FIGS. 3A-3C, the adjacent two two-port SRAM cells Cell-1 and Cell-2 are abutted together and form a rectangular cell shape (see FIG. 2) to have an X-pitch P1 (or cell dimension in word-line routing direction) and a Y-pitch P2 (or cell dimension in bit-line routing direction). The Y-pitch extends in a bit-line routing direction and a dimension thereof is about 4 times gate pitch (i.e., contacted poly pitch, CPP). By way of example and not limitation, a ratio of the X-pitch Pl to the Y-pitch P2 can be in a range from about 2.5 to 4, such as about 2.5, 3, 3.5, or 4. Therefore, the SRAM cell Cell-1 or Cell-2 may have an area equal to (P1*P2)/2. In a cell X-pitch direction, the SRAM cell Cell-1 or Cell-2 may have to 2.5 channel layers extending in the bit-line routing direction to have highly capability for cell scaling. On the other hand, the two abutted SRAM cells Cell-1 and Cell-2 may have five channel layers. In some embodiments, the channel layers can be interchangeably referred to channel patterns, OD lines, or active regions. In some embodiments, each of the two abutted SRAM cells Cell-1 and Cell-2 can be a two-port eight-transistor (8T) SRAM cell to have sixteen transistors formed upon (i.e., two transistors W-PU-1, two transistors W-PU-2, two transistors W-PD-1, two transistors W-PD-2, two transistors W-PG-1, two transistors W-PG-2, two transistors R-PD, and two transistors R-PG).

A symmetrical device layout can enhance cell stability and address device mismatch. From the perspective of minimizing device mismatch, the SRAM cells (e.g., SRAM cells Cell-1 and Cell-2) can share an identical layout environment, including uniformity in channel layers, gate structures, metallization layers, and metallization interconnect vias, ensuring consistency across cells, improving stability and reducing the likelihood of mismatches within the cell architecture. An cell array structure with the two abutted SRAM cells Cell-1 and Cell-2 in the symmetrical device layout can achieve both high density (e.g., less channel layers and metal lines in each layer) and high speed (e.g., lower RC delay for both bit-line and word-line).

In FIGS. 3A-3C, each of the SRAM cells Cell-1 and Cell-2 can have at least two ports (i.e., write-port and read-port) and includes at least three pass-gate devices (e.g., transistors W-PG-1, W-PG-2, and R-PG), at least three pull-down devices (e.g. transistors W-PD-1, W-PD-2, and R-PD), and at least two pull-up devices (e.g., transistors W-PU-1 and W-PU-2). The write-port includes two cross coupled inverters including four transistors W-PD-1, W-PU-1, W-PD-2, W-PU-2 and further includes two transistors W-PG-1 and W-PG-2. The read-port includes cascaded transistors R-PG and R-PD. The transistors W-PG-1, W-PG-2, R-PG, W-PD-1, W-PD-2, R-PD, W-PU-1, and W-PU-2 can be all formed by either FinFET transistor or vertically stacked gate-all-around (VS-GAA) horizontal nanosheets transistors. Said FinFET transistor can be single-fin, or multiple fin, or combination. Said VS-GAA can be single channel, or multiple vertically stacked nano-sheet (or nano-wire), or combination. In some embodiments, the transistors W-PG-1, W-PG-2, R-PG, W-PD-1, W-PD-2, R-PD, W-PU-1, and W-PU-2 may be MOS transistors with silicon channel layers. In some embodiments, the transistors W-PG-1, W-PG-2, R-PG, W-PD-1, W-PD-2, R-PD, W-PU-1, and W-PU-2 may be GAA FETs. The silicon channel layers of the transistors W-PG-1, W-PG-2, R-PG, W-PD-1, W-PD-2, R-PD, W-PU-1, and W-PU-2 may be formed by channel layers 210 wrapped by the gate structure 220. The channel layers 210 each can be semiconductor sheets stacked along the Z-direction (not shown) and, and the Z-direction is perpendicular to the plane formed by the X-direction and Y-direction, and the gate structure 220 can extend in the Y-direction. The gate structure 220 can be connected to an overlying level (e.g., read word-line M2-R-WL or read word-line M4-W-WL as shown in FIG. 3C) through a gate via 250. In some embodiments, the gate structure 220 can be interchangeably referred to a gate, a gate pattern, a gate strip, or a gate layer.

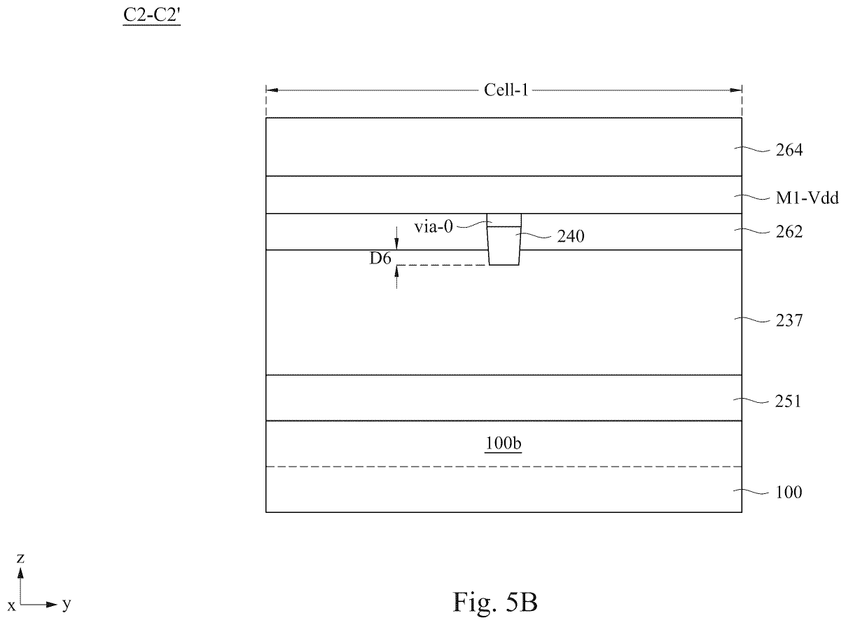

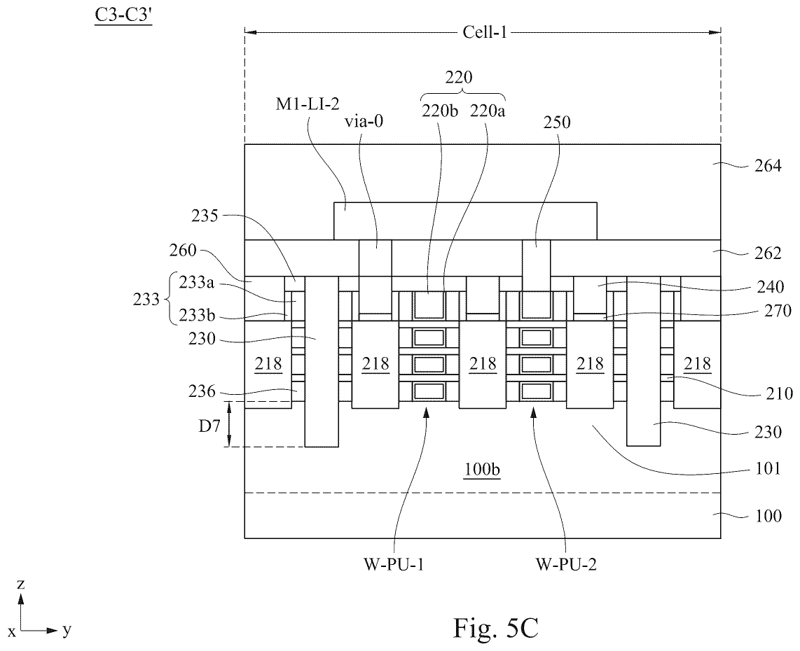

As shown in FIGS. 3A-3C, the transistors W-PU-1, W-PD-1, and R-PD may share one of the gate structures 220, and the transistors W-PU-2 and W-PD2 may share another one of the gate structures 220. In the SRAM cell Cell-1, the write-port transistors W-PU-1 and W-PU-2 may be formed on a first one of the channel layers 210, the write-port transistors W-PG-1, W-PG-2, W-PD-1, and W-PD-2 may be formed on a second one of the channel layers 210, and the read-port transistors R-PD and R-PG may be formed on a third one of the channel layer 210. In the SRAM cell Cell-2, the read-port transistors R-PD and R-PG of the SRAM cell Cell-2 may also be formed on the third one of the channel layers 210 as the read-port transistors R-PD and R-PG of the SRAM cell Cell-1, the write-port transistors W-PG-1, W-PG-2, W-PD-1, and W-PD-2 may be formed on a fourth one of the channel layers 210, and the write-port transistor W-PU-1 and W-PU-2 may be formed on a fifth one of the channel layers 210. The source node of two transistors W-PD-1, two transistors W-PD-2, and two R-PD of the SRAM cells Cell-1 and Cell-2 share one longer source/drain contact 240 and electrically connected to the power supply voltage line M3-Vss through the source/drain via via-0. The semiconductor structure further includes source/drain regions 218 (see FIG. 5C) between the gate structures 220 coupled to an overlying level (e.g., the power supply voltage line M3-Vss).

FIGS. 3A, 3C, and 3D illustrate the layout of metal lines in accordance with some embodiments. An interconnect structure is formed over the device region formation. The interconnect structure may include, for example, four metallization layers, labeled as M1, M2, M3, and M4, with two layers of metallization interconnect via via-0, via-1, via-2, and via-3. Other embodiments may contain more or fewer metallization layers and corresponding more or fewer number of interconnect vias. The metal lines in the metallization layer illustrated here just for an example, and the metal lines may be otherwise oriented (rotated 90 degrees or at other orientations). The interconnect structure includes a full metallization stack, including the metallization layers M1 and M2 connected by the interconnect via via-1 (see FIG. 3D), the metallization layers M2 and M3 connected by the interconnect via via-2 (see FIG. 3D), and the metallization layers M3 and M4 connected by the interconnect via via-3 (see FIG. 3D). The source/drain via via-0 (see FIGS. 3A and 3B) can connect the full metallization stack to the source/drain region 218 (see FIG. 5C) in the device region. In some embodiments, the metallization layers M1, M2, M3, and M4 can be interchangeably referred to first, second, third, and fourth metal line levels of the semiconductor structure 10 over the device region formation. Also included in the interconnect structure is an inter-metal dielectric (IMD) layer 264 (see FIGS. 5A-5C). The IMD layer 264 may provide electrical insulation as well as structural support for the various features of the interconnect structure.

In some embodiments, the write-port of the abutted SRAM cells Cell-1 and Cell-2 may include a write word-line M4-W-WL-1 (see FIG. 3D), a write word-line M4-W-WL-2 (see FIG. 3D), a write bit-line M3-W-BL (see FIG. 3D), a write bit-line-bar M3-W-BLB (see FIG. 3D) to serve write functionality. The read-port of the abutted SRAM cells Cell-1 and Cell-2 may include a read word-line M2-R-WL-1 (see FIG. 3D), a read word-line M2-R-WL-2 (see FIG. 3D), and a read bit-line M1-R-BL (see FIGS. 3A and 3C).

Throughout the description, the notations of metal lines may be followed by the metal line levels they are in, wherein the respective metal line level is placed in parenthesis. As shown in FIGS. 3A and 3C, metal lines disposed at the M1 level may include two power supply voltage lines M1-Vdd and a read bit-line M1-R-BL. The metal lines disposed at the M1 level may further include a power supply voltage line landing pad M1-Vss, two read word-line landing pads M1-R-WL-1, two read word-line landing pads M1-R-WL-2, two write bit-line landing pads M1-W-BL, two write bit-line-bar landing pads M1-W-BLB, a write word-line landing pads M1-W-WL-1, a write word-line landing pads M1-W-WL-2, two local connection lines M1-L1-1, and two local connection lines M1-L1-2. The local connection lines M1-L1-1, M1-L1-2 can be used for connecting a write port data node contact to another CMOS gate connection. Specifically, the local connection line M1-L1-1 can form an electrically connection between the gate structure 220 of the transistor W-PD-1 and the drain node of the transistor W-PG-2. The local connection line M1-L1-2 can form an electrically connection between the gate structure 220 of the transistor W-PD-2 and the drain node of the transistor W-PD-1.

In some embodiments, placing the SRAM bit-lines in the lowest metallization layer (e.g., metallization layer M1) can reduce bit-line capacitance to enhance cell speed. However, utilizing the lowest metal level may push the limits of metal pitch, for increasing the density of logic circuit routing. As the metal thickness and line width continue to decrease, the resistance of the SRAM bit-line and Vss conductors increases, which can lead to voltage drops (e.g., IR drop concerns) and adversely affect cell speed and minimum operational voltage (V_min) performance. Therefore, for the read port, the speed can be influenced by the on-current of the transistor (Ion) and the bit-line capacitance. Keeping the read bit-line (e.g., read bit-line M1-R-BL) in the lowest metallization layer (e.g., metallization layer M1) can minimizes capacitance, thereby reducing the metal landing pad capacitance that would otherwise increase if the read bit-line were positioned in a higher metal layer.

The metal lines disposed at the M1 level over the SRAM cell Cell-1 or Cell-2 can each have a rectangular shape. The metal lines disposed at the M1 level may have lengthwise directions parallel to the Y-direction (e.g., column direction). Accordingly, each of these metal lines disposed at the M1 level may extend into, and may be connected to, a plurality of SRAM cells in the same column. In some embodiments, the read bit-line M1-R-BL can be located between the power supply voltage lines M1-Vdd. In some embodiments, the power supply voltage lines M1-Vdd, the read bit-line M1-R-BL, the power supply voltage line landing pad M1-Vss, the read word-line landing pads M1-R-WL-1 and M1-R-WL-2, the write bit-line landing pads M1-W-BL, the write bit-line-bar landing pads M1-W-BLB, the write word-line landing pads M1-W-WL-1 and M1-W-WL-2, the local connection lines M1-L1-1 and M1-L1-2 can be interchangeably referred to conductive lines, line patterns, metal layers, conductive layers, or conductors.

As shown in FIG. 3D, metal lines disposed at the M2 level may include a read word-line M2-R-WL-1 and a read word-line M2-R-WL-2. The metal lines disposed at the M2 level may further include a power supply voltage line landing pad M2-Vss, a write bit-line landing pad M2-W-BL, a write bit-line-bar landing pad M2-W-BLB, and a write word-line landing pad M2-W-WL-1, and a write word-line landing pad M2-W-WL-2. The metal lines disposed at the M2 level over the SRAM cell Cell-1 or Cell-2 each can have a rectangular shape. The metal lines disposed at the M2 level may have lengthwise directions parallel to the X-direction (e.g., row direction). Accordingly, each of these metal lines disposed at the M2 level may extend into, and may be connected to, a plurality of SRAM cells in the same row. In some embodiments, the power supply voltage line landing pad M2-Vss and the two write word-line landing pads M2-W-WL can be located between the read word-line M2-R-WL-1 and the read word-line M2-R-WL-2. In some embodiments, the read word-line M2-R-WL-1 and M2-R-WL-2, the power supply voltage line landing pad M2-Vss, the write bit-line landing pad M2-W-BL, a write bit-line-bar landing pad M2-W-BLB, and the write word-line landing pads M2-W-WL-1 and M2-W-WL-2 can be interchangeably referred to conductive lines, line patterns, metal layers, conductive layers, or conductors.

In some embodiments, at the M2 level shown in FIG. 3D, the write word-line landing pad M2-W-WL-1 can serve to unite the pass-gate drain nodes of pass-gate transistors W-PG-1 across multiple cells (e.g., SRAM cells Cell-1 and Cell-2). The write word-line landing pad M2-W-WL-1 can be then connected to the write bit-line (e.g., write bit-line M3-W-BL) located on the next higher level (e.g., metallization layer M3) and can be aligned with the direction of word-line routing. Similarly, the write word-line landing pad M2-W-WL-2 at the M2 level shown in FIG. 3D can serve to unite the pass-gate drain nodes of pass-gate transistors W-PG-2 across multiple cells (e.g., SRAM cells Cell-1 and Cell-2). The write word-line landing pad M2-W-WL-2 can be then connected to the write bit-line bar (e.g., write bit-line M3-W-BLB) located on the next higher level (e.g., metallization layer M3) and can be aligned with the direction of word-line routing.

As shown in FIG. 3D, metal lines disposed at the M3 level may include a power supply voltage line M3-Vss, a write bit-line M3-W-BL, and a write bit-line-bar M3-W-BLB. The metal lines disposed at the M3 level may further include a write word-line landing pad M3-W-WL-1 and a write word-line landing pad M3-W-WL-2. The metal lines disposed at the M3 level over the SRAM cell Cell-1 or Cell-2 each can have a rectangular shape. The metal lines disposed at the M3 level may have lengthwise directions parallel to the Y-direction (e.g., column direction) as the metal lines disposed at the M1 level. Accordingly, each of these metal lines disposed at the M3 level may extend into, and may be connected to, a plurality of SRAM cells in the same column. In some embodiments, the power supply voltage line M3-Vss can be located between the write bit-line M3-W-BL and the write bit-line-bar M3-W-BLB. In some embodiments, the supply voltage line M3-Vss, the write bit-line M3-W-BL, and the write bit-line-bar M3-W-BLB, and the write word-line landing pads M3-W-WL-1 and M3-W-WL-2 can be interchangeably referred to conductive lines, line patterns, metal layers, conductive layers, or conductors.

In some embodiments, the write margin of the SRAM cells Cell-1 and Cell-2 can be determined by the resistance of the write bit-line. The write bit-line (e.g., write bit-line M3-W-BL and write bit-line-bar M3-W-BLB) can be elevated to a higher metallization layer (e.g., metallization layer M3) to reduce resistance, enhancing overall cell performance. As a result, the read and write bit-lines can be segregated onto two distinct metallization layers (e.g., metallization layer M1 for the read bit-line and metallization layer M3 for the write bit-line and its counterpart, the write bit-line-bar), allowing for a reduction in bit-line capacitance and resistance, improving the SRAM cell's efficiency and performance.

As shown in FIG. 3D, metal lines disposed at the M4 level may include a power supply voltage line M4-Vss, a write word-line M4-W-WL-1, and a write word-line M4-W-WL-2. The metal lines disposed at the M4 level over the SRAM cell Cell-1 or Cell-2 each can have a rectangular shape. The metal lines disposed at the M4 level may have lengthwise directions parallel to the X-direction (e.g., row direction) as the metal lines disposed at the M2 level. Accordingly, each of these metal lines disposed at the M4 level may extend into, and may be connected to, a plurality of SRAM cells in the same row. In some embodiments, the power supply voltage line M4-Vss can be located between the write word-line M4-W-WL-1 and a write word-line M4-W-WL-2 and electrically connected to the power supply voltage line M3-Vss. In some embodiments, the power supply voltage line M4-Vss the a write word-lines M4-W-WL-1 and M4-W-WL-2 can be interchangeably referred to conductive lines, line patterns, metal layers, conductive layers, or conductors.

The read word-lines (e.g., read word-lines M2-R-WL-1 and M2-R-WL-2) and write word-lines (e.g., write word-lines M4-W-WL-1 and M4-W-WL-2) can be positioned on separate metallization layers M2 and M4, respectively. This arrangement can segregate read and write operations across different metal levels to enhance the efficiency and reliability of the SRAM cell operations. In some embodiments, by isolating the read and write circuits to different layers (e.g., metallization layers M2 and M4), electrical interference between read and write operations can be minimized, reducing the potential for signal crosstalk and noise, which can degrade the speed and accuracy of SRAM operations.

The source/drain vias (e.g., interconnect via via-0 shown in FIGS. 3A and 3B) disposed at the via-0 level may be formed in order to connect to the corresponding source/drain regions 218 (see FIG. 5C) to the corresponding metal lines at the M1 level. The interconnect vias (e.g., interconnect via via-1 shown in FIG. 3D) disposed at the via-1 level may be formed in order to connect to the corresponding metal lines at the M1 level to the corresponding metal lines at the M2 level. The interconnect vias (e.g., interconnect via via-2 shown in FIG. 3D) disposed at the via-2 level may be formed in order to connect to the corresponding metal lines at the M2 level to the corresponding metal lines at the M3 level. The interconnect vias (e.g., interconnect via via-3 shown in FIG. 3D) disposed at the via-3 level may be formed in order to connect to the corresponding metal lines at the M3 level to the corresponding metal lines at the M4 level. In some embodiments, the interconnect vias can have a rectangular shape.

In some embodiments, the layouts as shown in FIGS. 3A-3D are represented by a plurality of masks generated by one or more processors and/or stored in one or more non-transitory computer-readable media. Other formats for representing the layout are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

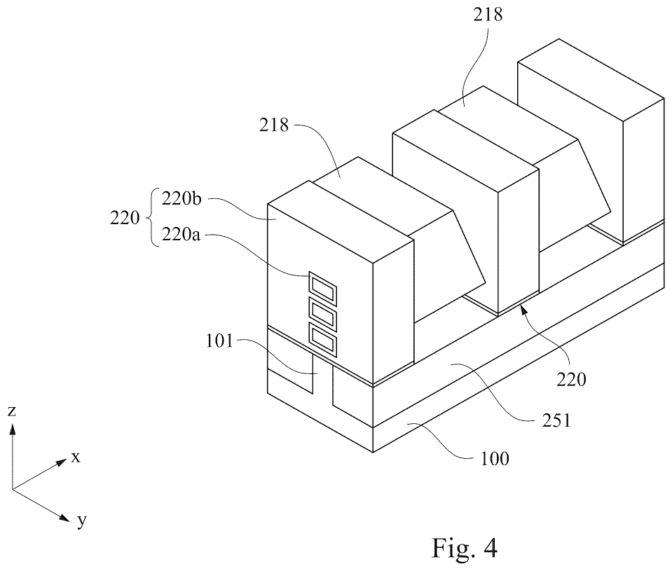

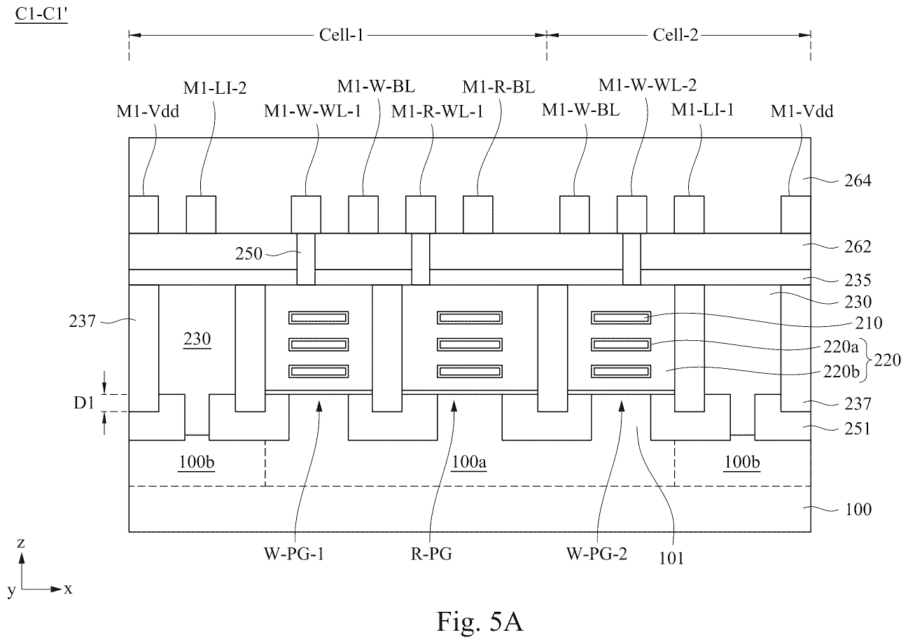

Reference is made to FIGS. 4-5C. FIG. 4 illustrates a perspective view of an example nano-FET device in accordance with some embodiments of the present disclosure. The transistors formed in FIGS. 1-3D can employ the nano-FET as shown in FIG. 4. FIGS. 5A-5C illustrate schematic cross-sectional views obtained from reference cross-section C1-C1′, C2-C2′, and C3-C3′ in FIG. 3A, respectively. In some embodiments, the nano-FET may be nanosheet field-effect transistors (NSFETs), nanowire field-effect transistors (NWFETs), gate-all-around field-effect transistors (GAAFETs), or the like. In some embodiments, the transistor shown in FIG. 4 can include the channel regions 210, the source/drain regions 218 on opposite sides of the channel regions 210, and the gate structure 220 wrapping around the channel regions 210.

Specifically, as shown in FIGS. 5A-5C. The substrate 100 is provided for forming nano-FETs. The substrate 100 may be a semiconductor substrate, such as a bulk semiconductor, a semiconductor-on-insulator (SOI) substrate, or the like, which may be doped (e.g., with a p-type or an n-type impurity) or undoped. The substrate 100 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the substrate 100 may be a material, such as a III-V compound semiconductor, a II-VI compound semiconductor, or the like. In some embodiments, the semiconductor material of the substrate 100 may include silicon; germanium; a compound semiconductor including silicon carbide, gallium arsenide, gallium stannum, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 100 may be lightly doped with a p-type or an n-type impurity to form a first conductivity type well region 100a and a second conductivity type well region 100b having an opposite conductivity type to the first conductivity type well region. An anti-punch-through (APT) implantation may be performed on an upper portion of the substrate 100 to form an APT region. During the APT implantation, impurities may be implanted in the substrate 100. The impurities may have a conductivity type opposite from a conductivity type of source/drain regions that will be subsequently formed in each of the n-type region and the p-type region. The APT region may extend under the source/drain regions in the nano-FETs. The APT region may be used to reduce the leakage from the source/drain regions to the substrate 100. In some embodiments, the doping concentration in the APT region may be in the range of about 10¹⁸ cm⁻³ to about 10¹⁹ cm⁻³. By way of example and not limitation, first conductivity type well region 100a can be a P-type well region, and the second conductivity type well region 100b can be an N-type well region. In some embodiments, the P-type well region can have n-type devices, such as NMOS transistors, formed thereon, and the N-type well region can have p-type devices, such as PMOS transistors, formed thereon.

Trenches T1 (see FIG. 5A) formed in the substrate 100 defining the fin strip 101 (see FIG. 5A). In the other words, the fin strip 101 is semiconductor strip patterned in the substrate 100. A shallow trench isolation (STI) structure 251 (see FIGS. 5A and 5B) can be formed over the substrate 100 and laterally surround the fin strip 101. In some embodiments, the top surface of the STI structure 251 is coplanar (within process variations) with a top surface of the fin strip 101. In some embodiments, the top surface of the STI structure 251 is above or below the top surface of the fin strip 101. In some embodiments, the STI structure 251 may separate the features of adjacent devices.

The channel layers 210 (see FIGS. 5A and 5C) are stacked along the Z-direction over the fin strip 101 and act as active regions. In some embodiments, the channel regions 210 may include p-type nanostructures, n-type nanostructures, or a combination thereof and extend along an X-direction. For example, the channel layer 210 can be a silicon sheet that forms a silicon channel layer for the corresponding transistor. In some embodiments, channel layer 210 may have a width in a range from about 4 nm to about 7 nm when viewed in X-direction. In some embodiments, the number of stacked channel layers 210 may be between about 2 to about 10. In some embodiments, the thickness of the channel layer 210 may be within a range about 3 nm to about 10 nm. In some embodiments, the channel regions 210 can be interchangeably referred to as channel patterns, nanostructures, nanosheets, semiconductor sheets, or nanowires.

The gate structures 220 (see FIGS. 5A and 5C) may include one or more gate electrode layer 220b and a gate dielectric layer 220a. The gate dielectric layers 220a can be formed over top surfaces of the fin strip 101 and along top surfaces, sidewalls, and bottom surfaces of the channel regions 210. The gate electrode layers 210b are formed over the gate dielectric layer 220a. In some embodiments, the gate electrode layer 220b may be made of conductive material, such as aluminum (Al), copper (Cu), tungsten (W), titanium (Ti), tantalum (Ta), or other applicable materials. In some embodiments, the gate electrode layer 220b may include multiple material structure selected from a group consisting of poly gate/SiON structure, metals/high-K dielectric structure, Al/refractory metals/high-K dielectric structure, silicide/high-K dielectric structure, or combination. In some embodiments, the gate electrode layers 210b may include one or more work-functionlayers (not shown). In some embodiments, the work function layer can be made of metal material, and the metal material may include N-work-function metal or P-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal may include titanium nitride (TiN), tungsten nitride (WN), tantalum nitride (TaN), ruthenium (Ru) or a combination thereof. In some embodiments, the gate electrode layer 220b is formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

In some embodiments, the gate dielectric layer 220a can be made of silicon oxide (SiOₓ), silicon nitride (SiₓN_{y}), silicon oxynitride (SiON), dielectric material(s) with high dielectric constant (high-k), or a combination thereof. The high dielectric constant (high-k) material may be hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. In some embodiments, the gate dielectric layer 220a includes Lanthanum (La) dopant. In some embodiments, the gate dielectric layer 220a can be deposited by a plasma enhanced chemical vapor deposition (PECVD) process or by a spin coating process.

The source/drain regions 218 (see FIG. 5C) may include silicon with boron (e.g., B₁₁) content. In some embodiments, the source/drain regions 218 can be formed by epitaxially growing boron in Si material. In some embodiments, the source/drain regions 218 may include materials and/or dopants that achieve desired tensile stress and/or compressive stress in the channel layer 210. In some embodiments, the source/drain regions 218 can be interchangeably referred to epitaxial structures, source/drain structures, or source/drain patterns. In some embodiments, source/drain silicide regions 270 (see FIG. 5C) are formed on a top of the source/drain regions 218. In some embodiments, a bottom of the source/drain regions 218 can be in contact with the well region. In some embodiments, a dielectric layer can be formed to sandwich between the source/drain region 218 and the well region.

the S/D bottom regions can be either connected to Well regions or had bottom dielectric layer located between S/D and Well regions.

Gate spacers 233 (see FIG. 5C) are formed on the sidewalls of the gate structure 220. In some embodiments, the gate spacer 233 may be made of SiO₂, Si₃N₄, SiON, SiOC, SiOCN base dielectric material, air gap, or combinations thereof. In some embodiments, the gate spacer 233 may be made of a low-dielectric constant (low-k) materials having a k-value less than about 3.5, may be utilized. In some embodiments, the gate spacers 233 can be constructed from multiple layers to enhance device performance and reliability. Specifically, these spacers can include at least two distinct layers 233a and 233b, stacked upon each other on the sidewalls of the gate structure 220. The layer 233a can be deposited onto the gate structure 220 before the formation of the source/drain regions 218. Following the establishment of the source/drain regions 218, the layer 233b can be then added atop the layer 233a, further encapsulating the gate structure 220. This subsequent layer 233b can serve to enhance the isolation between the gate structure 220 and the source/drain regions 218, potentially reducing leakage currents and improving the transistor's overall performance. In some embodiments, the layer 233b can be made of a different material than the layer 233a. In some embodiments, the layer 233b can be made of the same material as the layer 233a.

Inner spacers 236 (see FIG. 5C) may be formed between the source/drain regions 218 and the gate structure 220 and act as isolation features. In some embodiments, the inner spacers 236 can be interchangeably referred to lower gate spacers. In some embodiments, the inner spacers 236 may have a lateral dimension in a range from about 4 nm to about 12 nm.

Hard mask layer 235 (see FIGS. 5A and 5C) can be formed over the gate structure 220 and the gate spacers 233. In some embodiments, the hard mask layer 235 can be interchangeably referred to a gate top dielectric. In some embodiments, the hard mask layer 235 may be made of dielectric material. In some embodiments, the top surface of the hard mask layer 235 may be aligned with the top surfaces of the source/drain contacts 240 (see FIG. 5C). In some embodiments, the top surface of the hard mask layer 235 may be lower than the top surfaces of the source/drain contacts 240. In some embodiments, the hard mask layer 235 may be made of a nitride-based material, such as Si₃N₄, SiON, or a carbon-based material, such as SiC, SiOC, SiOCN, or combinations thereof. In some embodiments, the hard mask layer 235 may include SiOₓ, SiBN, SiCBN, other suitable dielectric materials, or combinations thereof. In some embodiments, the hard mask layer 235 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

Gate end dielectric structures 237 (see FIGS. 5A and 5B) can act as gate-cut structures for the gate structure 220. In some embodiments, the gate end dielectric structures 237 can be placed at the edges of grouped cells, adjacent to the pull-up transistors W-PU-1 and W-PU-2. In some embodiments, the gate end dielectric structure 237 can span the entire cell height H1 of the SRAM cells Cell-1 and Cell-2 along the bit-line routing direction. The gate end dielectric structure 237 can mitigate the bridging of epitaxial growth across different source/drain regions 218, thus allowing for the maximization of the size of the source/drain region 218 to abut and halt at the gate end dielectric structure 237. Enlarging the source/drain regions 218 can not only lower their resistance but also facilitate the incorporation of strain layers, such as SiGe for PMOSFETs, enhancing carrier mobility due to the increased volume of the source/drain region 218. Therefore, the source/drain region 218 can be in contact with the gate end dielectric structure 237 and the longitudinal end of the gate structure 220. In some embodiments, the gate end dielectric structure 237 can have a portion embedded in the STI structure 251 and having a vertical dimension D1 in a range from about 5-60 nm, such as about 5, 10, 15, 20, 25, 30, 35, 40, 45, 50, 55, or 60 nm. In some embodiments, the gate end dielectric structure 237 can be interchangeably referred to a dielectric line, an isolation structure, a gate end dielectric line, a gate end dielectric strip, a gate end dielectric pattern, an isolation structure an isolation strip, a dielectric strip, or a dielectric region.

In some embodiments, the gate end dielectric structure 237 may be formed of or comprise SiO₂, SiOC, SiOCN, or the like, or combinations thereof. In some embodiments, the gate end dielectric structure 237 may be made of a nitride-based material, such as Si₃N₄, or a carbon-based material, such as SiOCN, or combinations thereof. In some embodiments, the gate end dielectric structure 237 may be made of a metal oxide material. In some embodiments, the gate end dielectric structure 237 may be made of a material having a dielectric constant greater than about 9 (e.g., high dielectric constant (high-k) material). For example, the gate end dielectric structure 237 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The gate end dielectric structure 237 may be formed of a homogenous material, or may have a composite structure including more than one layer. In some embodiments, the gate end dielectric structure 237 may include dielectric liners, which may be formed of, for example, silicon oxide.

An inter-layer dielectric (ILD) layer 260 (see FIG. 5C) can be formed between the gate structures 220 and over the source/drain regions 218, and an ILD layer 262 (see FIGS. 5A-5C) can be formed over the hard mask layer 235 and the ILD layers 260.

Dielectric gates 230 (see FIGS. 5A and 5C) can be formed to replace with some gate structures 220. In SRAM designs, it's common to implement channel layer cuts (or in the oxide definition (OD)) at the drain-node ends of pull-up transistors W-PU-1 and W-PU-2 to isolate adjacent cells. This segmented channel layer 210, contrasting with the continuous channel layer 210 under the pass-gates W-PG-1, W-PG-2, and R-PG and pull-down transistors W-PD-1, W-PD-2, and R-PD, can lead to layout-induced effects (LOD) and mismatch issues between pass-gate and pull-down transistors. This happens because the pull-down transistor operates in a denser layout environment, whereas the pass-gate transistor encounters discontinuities in the channel layer 210. Therefore, a continuous channel layer 210 alongside the dielectric gate 230 can mitigate issues, such as channel layer end shrinkage control for pull-down transistors and improve layout effects. In some embodiments, the dielectric gate 230 can form an isolation region separating the source/drain regions of neighboring semiconductor devices from each other, and thus the different semiconductor devices can be separated.

The dielectric gate 230, placed between the gate spacer 233, can interrupt the channel layer 210 at a depth surpassing the bottom of adjacent source/drain regions 218. In some embodiments, the dielectric gate 230 can downwardly extend deeper than the top surface of the fin strip 101 by about a vertical dimension D7. By way of example and not limitation, the vertical dimension D7 can be in a range from about 15 to 150 nm, such as about 15, 20, 30, 40, 50, 60, 70, 80, 90, 100, 110, 120, 130, 140, or 150 nm. In some embodiments, the dielectric gate 230 can include a single layer or multiple layers of different dielectric materials. In some embodiments, the dielectric gate 230 can be interchangeably referred to a dielectric pattern, a dielectric strip, or a dielectric layer. As shown in FIG. 3A, the dielectric gate 230 can extend in the Y-direction and being dummy gates. The gate structures 220 are arranged between the dielectric gate 230 in the X-direction. The dielectric gates 230 can be formed in the boundary of the SRAM cells Cell-1 and Cell-2. The dielectric gate 230 may include a bottom end that replaces an upper portion of the fin strip 101 and is lower than the source/drain regions 218. The bottom end of the dielectric gate 230 has a narrower width than a top end of the dielectric gate 230. The material of the dielectric gate 230 is different from the material of the gate structures 220. In some embodiments, the dielectric gate 230 can be made of silicon oxide (SiOₓ), silicon nitride (SiₓN_{y}), silicon oxynitride (SiON), dielectric material(s), other suitable material, or a combination thereof.

The source/drain contacts 240 (see FIG. 5C) are formed in the ILD layer 260 and on the source/drain silicide regions 270. In some embodiments, the source/drain vias via-0 (see FIG. 5C) can be formed in the ILD layer 262 to land on the source/drain contacts 240. In some embodiments, the gate vias 250 (see FIGS. 5A and 5C) can be formed to pass through the ILD layer 262 and the hard mask layers 235 and land on the corresponding gate structures 220. In some embodiments, as shown in FIGS. 3A and 5B, the source/drain contact 240 (see FIG. 3A) landing on the epitaxial source/drain region 218 between pull-up transistors W-PU-1 and W-PU-2 can laterally extend to overlap the gate end dielectric structure 237 and further downwardly extend into the gate end dielectric structure 237 in a vertical dimension D6. By way of example and not limitation, the vertical dimension D6 can be in a range from about 3 to 50 nm, such as about 3, 5, 10, 15, 20, 25, 30, 35, 40, 45, or 50 nm.

An interconnect structure including metal lines and vias can be formed over the ILD layer 262 to electrically connect to the corresponding gate vias 250 or the corresponding source/drain vias via-0. The metal lines can include the power supply voltage lines M1-Vdd, the read bit-line M1-R-BL, the local connection lines M1-L1-1 and M1-L1-2, the read word-lines M2-R-WL-1 and M2-R-WL-2, the power supply voltage line M3-Vss, the write bit-line M3-W-BL, the write bit-line-bar M3-W-BLB, the power supply voltage line M4-Vss, and the write word-lines M4-W-WL-1 and M4-W-WL-2. The metal vias can include the interconnect vias via-1, via-2, and via-3. The IMD layer 264 may provide electrical insulation as well as structural support for the various features of the interconnect structure.

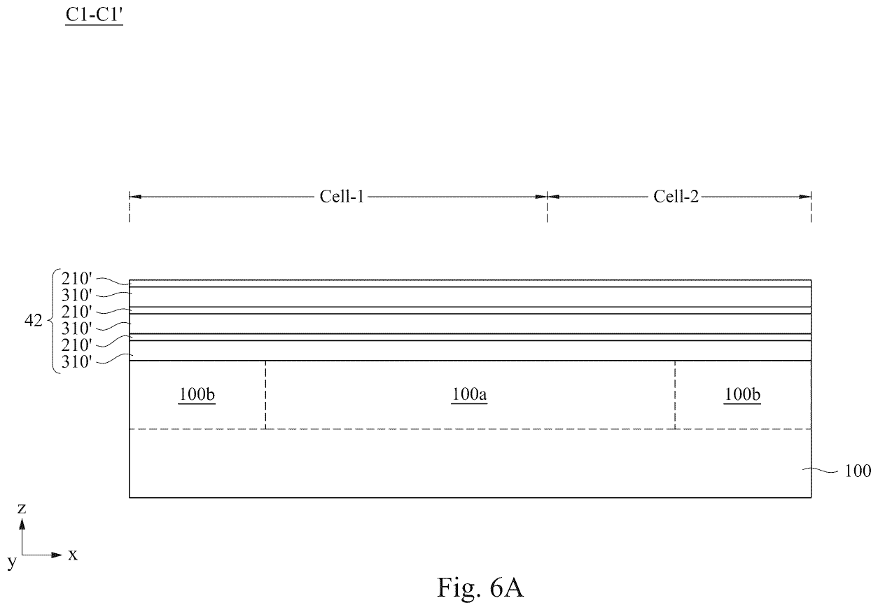

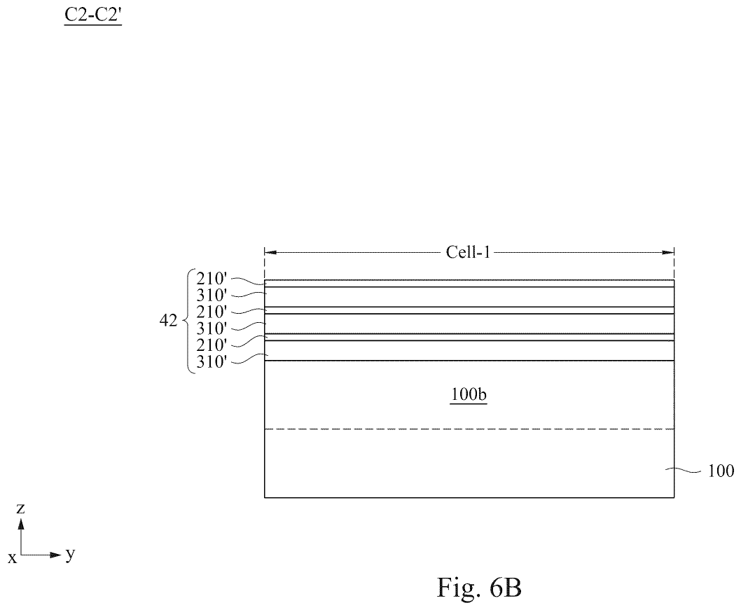

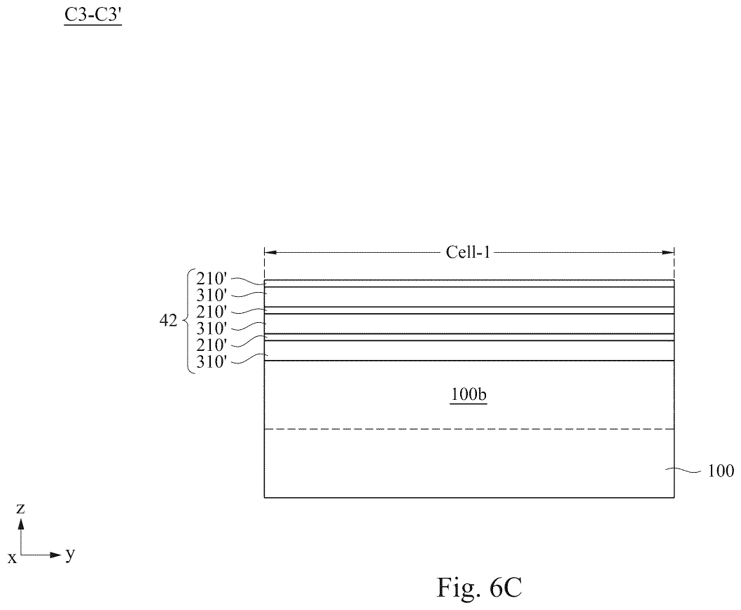

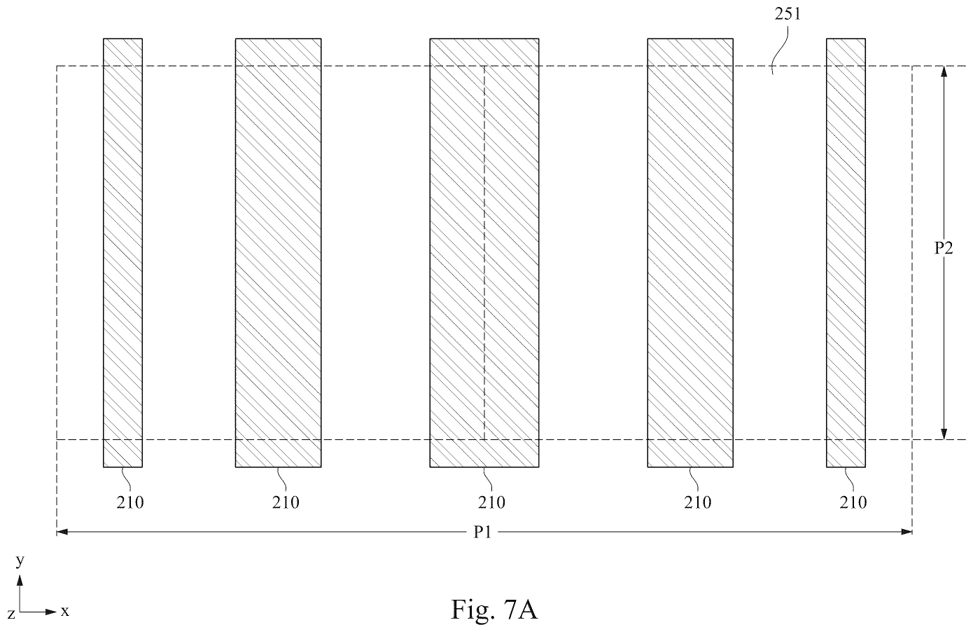

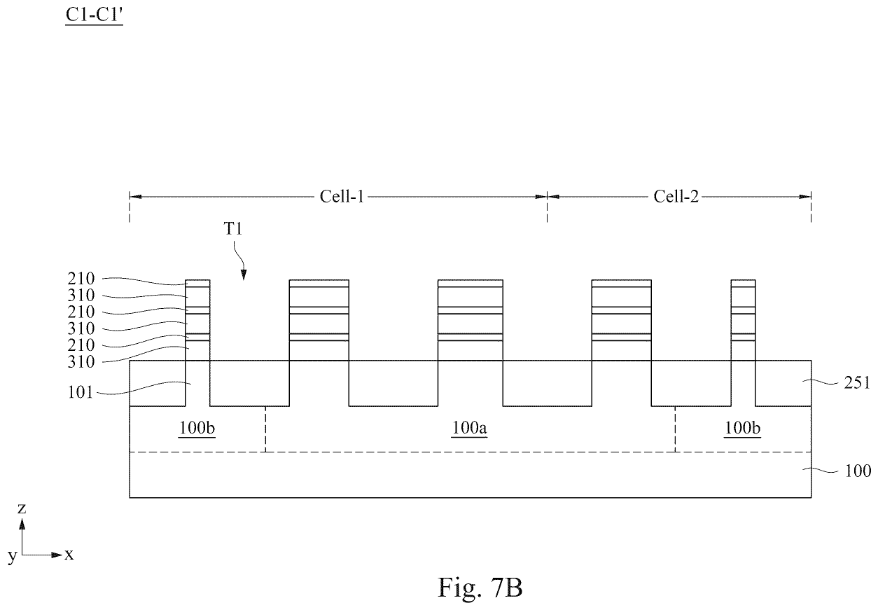

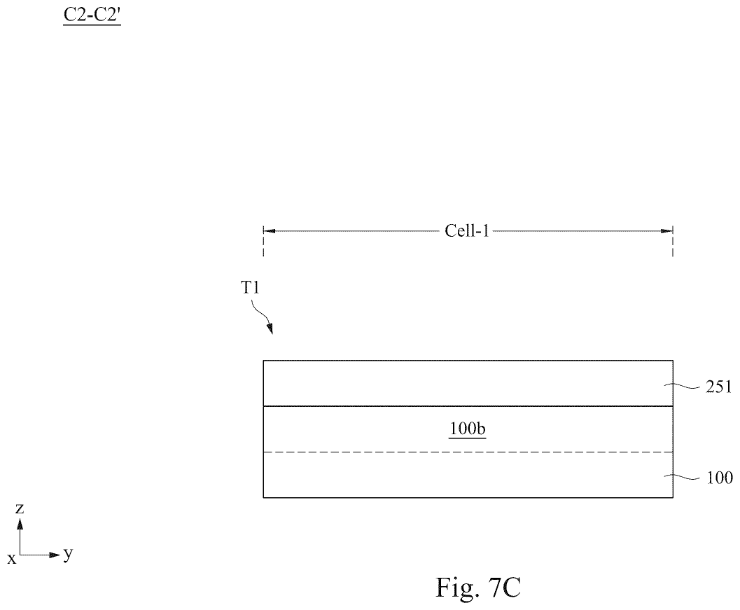

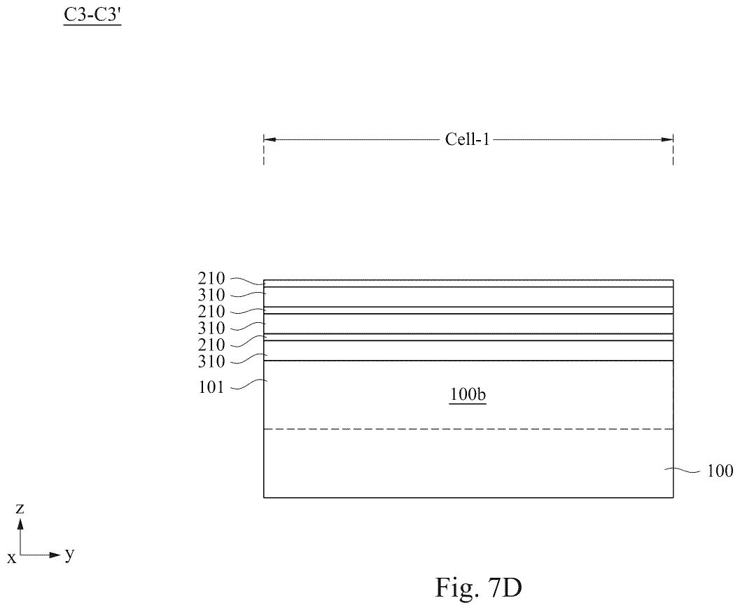

Reference is made to FIGS. 6A-17C. FIGS. 6A-17C illustrate schematic views of intermediate stages in the formation of a semiconductor structure in accordance with some embodiments. FIGS. 7A, 8A, 14A, and 15A illustrate top views of the semiconductor structure corresponding in accordance with some embodiments. FIGS. 6A, 7B, 8B, 9A, 10A, 11A, 12A, 13A, 14B, 15B, 16A, and 17A illustrate cross-sectional views of intermediate stages obtained from the reference cross-section C1-C1′ in the formation of the semiconductor structure in accordance with some embodiments. FIGS. 6B, 7C, 8C, 9B, 10B, 11B, 12B, 13B, 14C, 15C, 16B, and 17B illustrate cross-sectional views of intermediate stages obtained from the reference cross-section C2-C2′ in the formation of the semiconductor structure in accordance with some embodiments. FIGS. 6C, 7D, 8D, 9C, 10C, 11C, 12C, 13C, 14D, 15D, 16C, and 17C illustrate cross-sectional views of intermediate stages obtained from the reference cross-section C3-C3′ in the formation of the semiconductor structure in accordance with some embodiments.

As with the other method embodiments and exemplary devices discussed herein, it is understood that parts of the integrated circuit structure 100 may be fabricated by a CMOS technology process flow, and thus some processes are only briefly described herein. Further, the exemplary integrated circuit structure 100 may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary integrated circuit structure 100 includes a plurality of semiconductor devices (e.g., transistors), including PFETs, NFETs, etc., which may be interconnected. It is understood that additional operations can be provided before, during, and after the processes shown by FIGS. 2-10B, and some of the operations described below can be replaced or eliminated, for additional embodiments of the method. The order of the operations/processes may be interchangeable.

Reference is made to FIGS. 6A-6C. A substrate 100 is provided for forming nano-FETs. In some embodiments, material and manufacturing method of the substrate 100 is substantially the same as that shown in FIGS. 5A-5C, and the related detailed descriptions may refer to the foregoing paragraphs, and are not described again herein for the purpose of simplicity and clarity. A multi-layer stack 42 is formed over the substrate 100. The multi-layer stack 42 can include alternating first semiconductor layers 310′ and second semiconductor layers 210′. The first semiconductor layers 310′ formed of a first semiconductor material, and the second semiconductor layers 210′ are formed of a second semiconductor material different than the first semiconductor material. The semiconductor materials may each be selected from the candidate semiconductor materials of the substrate 100. In some embodiments, the multi-layer stack 42 includes two layers of each of the first semiconductor layers 310 and the second semiconductor layers 210′. It should be appreciated that the multi-layer stack 42 may include any number of the first semiconductor layers 310′ and the second semiconductor layers 210′.

In some embodiments, and as will be subsequently described in greater detail, the first semiconductor layers 310′ will be removed and the second semiconductor layers 210′ will patterned to form channel layers for the nano-FETs. The first semiconductor layers 310′ can be sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers in the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) may be formed to be thinner than other layers (e.g., the first semiconductor layers 310′).

Reference is made to FIGS. 7A-7D. Trenches TI can be patterned in the substrate 100 and the multi-layer stack 42 to form fin strips 101, semiconductor sheets 310, and channel layers 210. The fin strips 101 are semiconductor strips patterned in the substrate 100. The semiconductor sheets 310 and the channel layers 210 include the remaining portions of the first semiconductor layers 310′ and the second semiconductor layers 210′, respectively. The trenches T1 may be patterned by any acceptable etch process, such as a reactive ion etch (RIE), neutral beam etch (NBE), the like, or a combination thereof. The etching may be anisotropic. The fin strips 101, the semiconductor sheets 310, and the channel layers 210 may be patterned by any suitable method. For example, the fin strips 101, the semiconductor sheets 310, and the channel layers 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

The STI structures 251 can be formed over the substrate 100 and between adjacent fin strips 101. The STI structures 251 are disposed around at least a portion of the fin strips 101 such that at least a portion of the semiconductor sheet 310 and the channel layer 210 protrude from between adjacent STI structures 251. In some embodiments, the top surfaces of the STI structures 251 are coplanar (within process variations) with the top surfaces of the fin strips 101. The STI structures 251 may be formed by any suitable method. For example, an insulation material can be formed over the substrate 100 and the semiconductor sheets 310 and the channel layers 210, and between adjacent fin strips 101. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In some embodiments, the insulation material is formed such that excess insulation material covers the semiconductor sheets 310 and the channel layers 210. Although the STI structures 251 are each illustrated as a single layer, some embodiments may utilize multiple layers. For example, in some embodiments a liner (not separately illustrated) may first be formed along surfaces of the substrate 100, the fin strips 101, the semiconductor sheets 310, and the channel layers 210. Thereafter, a fill material, such as those previously described may be formed over the liner.

A removal process is then applied to the insulation material to remove excess insulation material over the semiconductor sheets 310 and the channel layer 210s. In some embodiments, a planarization process such as a chemical mechanical polish (CMP), an etch-back process, combinations thereof, or the like may be utilized. In embodiments in which a mask remains on the semiconductor sheets 310 and the channel layers 210, the planarization process may expose the mask or remove the mask. After the planarization process, the top surfaces of the insulation material and the mask (if present) or the semiconductor sheet 310/the channel layer 210 are coplanar (within process variations). Accordingly, the top surfaces of the mask (if present) or the semiconductor sheet 310/channel layer 210 can be exposed through the insulation material. In some embodiments, no mask remains on the semiconductor sheets 310 and the channel layers 210. The insulation material is then recessed to form the STI structures 251. The insulation material is recessed, such as in a range from about 30 nm to about 80 nm, such that at least a portion of the semiconductor sheets 310 and the channel layers 210 can protrude from between adjacent portions of the insulation material. Further, the top surfaces of the STI structures 251 may have a flat surface as illustrated, a convex surface, a concave surface (such as dishing), or a combination thereof. The insulation material may be recessed using any acceptable etching process, such as one that is selective to the material of the insulation material (e.g., selectively etches the insulation material of the STI structures 251 at a faster rate than the materials of the fin strips 101 and the semiconductor sheets 310 and the channel layers 210). For example, an oxide removal may be performed using dilute hydrofluoric (dHF) acid.

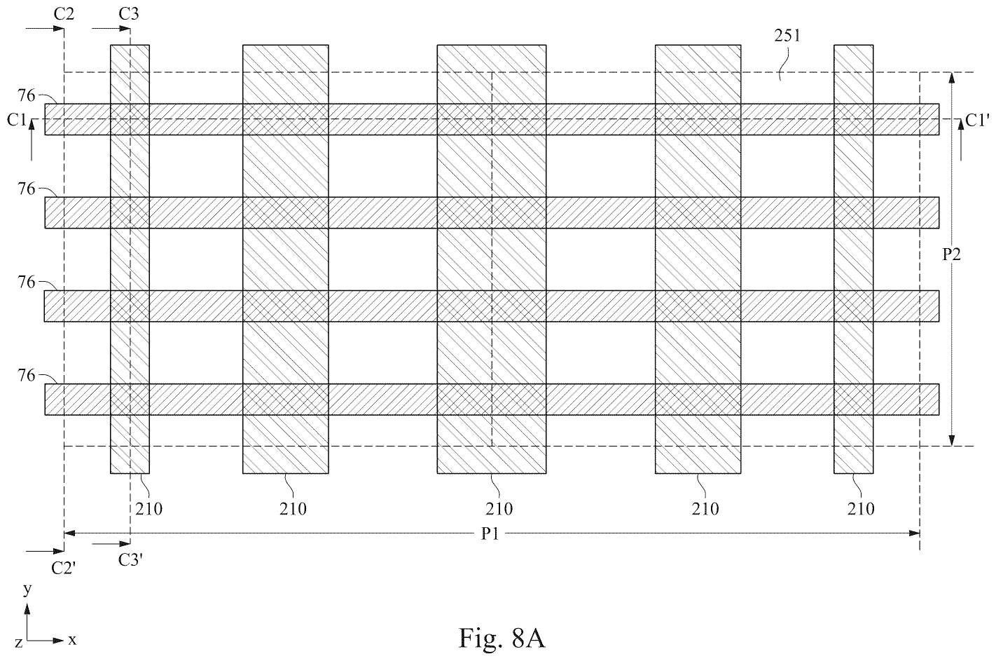

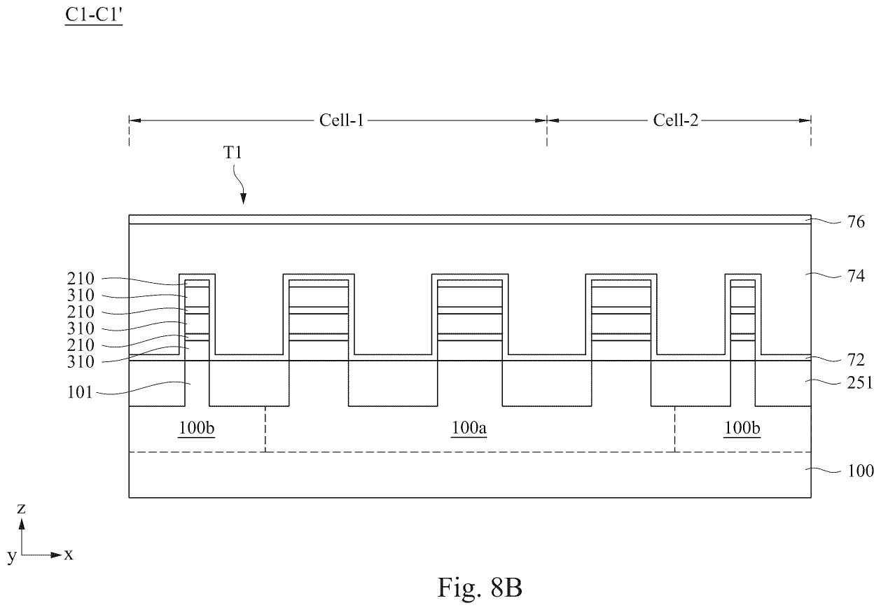

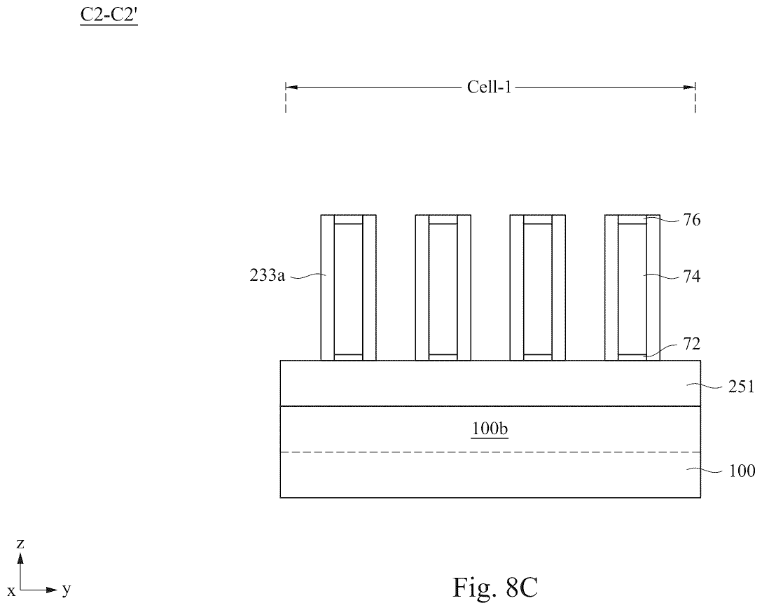

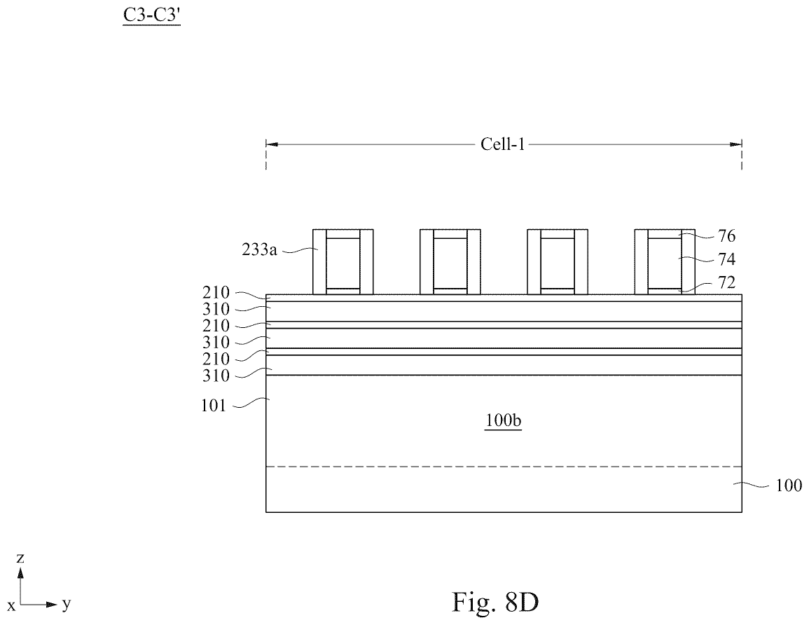

Reference is made to FIGS. 8A-8D. A dummy dielectric layer, a dummy gate layer, and a mask layer are sequentially formed on the fin strips 101, the semiconductor sheets 310, and the channel layers 210. The dummy dielectric layer is formed on the fin strips 101, the semiconductor sheets 310, and the channel layers 210. The dummy dielectric layer may be formed of a dielectric material such as silicon oxide, silicon nitride, a combination thereof, or the like, which may be deposited or thermally grown according to acceptable techniques. Subsequently, a dummy gate layer is formed over the dummy dielectric layer. Subsequently, a mask layer is formed over the dummy gate layer. The dummy gate layer may be deposited over the dummy dielectric layer and then planarized, such as by a CMP. The mask layer may be deposited over the dummy gate layer. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer. The mask layer may be formed of a dielectric material such as silicon nitride, silicon oxynitride, or the like.

The mask layer is patterned using acceptable photolithography and etching techniques to form masks 76. The pattern of the masks 76 is then transferred to the dummy gate layer and the dummy dielectric layer by any acceptable etching technique to form dummy gates 74. The pattern of the masks 76 may optionally be further transferred to the dummy dielectric layer by any acceptable etching technique to form dummy dielectrics 72. The dummy gates 74 cover portions of the semiconductor sheets 310 and the channel layers 210 that will be exposed in subsequent processing to form active regions. The dummy gates 74 may also have lengthwise directions substantially perpendicular (within process variations) to the lengthwise directions of the fin strips 101. The masks 76 can optionally be removed after patterning, such as by any acceptable etching technique.

The layers 233a serving as gate spacers can be formed over the semiconductor sheets 310 and the channel layers 210 and on exposed sidewalls of the masks 76 (if present), the dummy gates 74, and the dummy dielectrics 72. In some embodiments, the layer 233a can be interchangeably referred to top spacers or upper gate spacers. In some embodiments, the layer 233a may include multiple dielectric material and selected from a group consist of SiO₂, Si₃N₄, carbon doped oxide, nitrogen doped oxide, porous oxide, air gap, or combinations thereof. The layer 233a may be formed by conformally depositing one or more dielectric material(s) and subsequently etching the dielectric material(s). Acceptable dielectric materials may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 74 (thus forming the layer 233a).

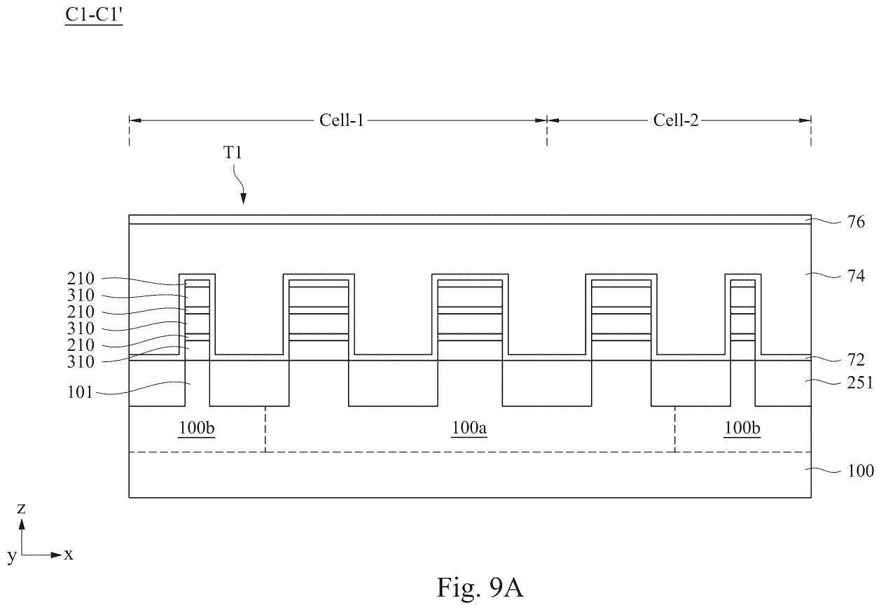

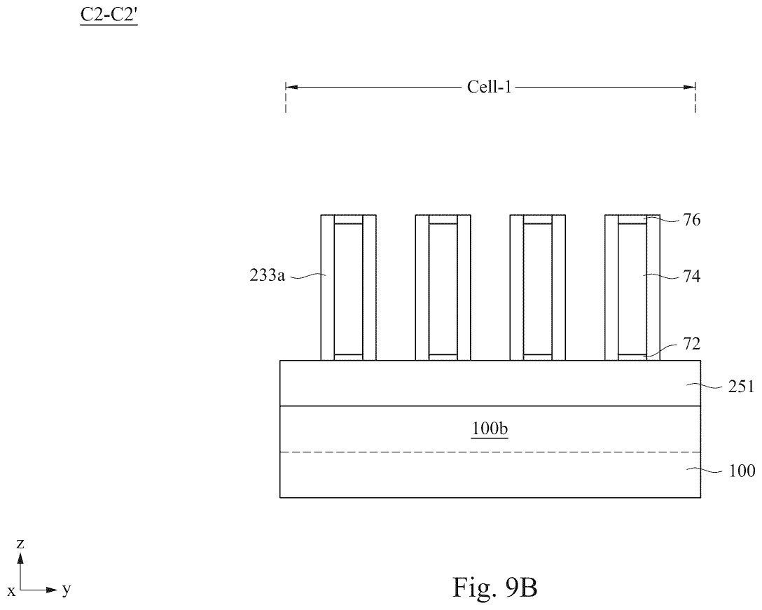

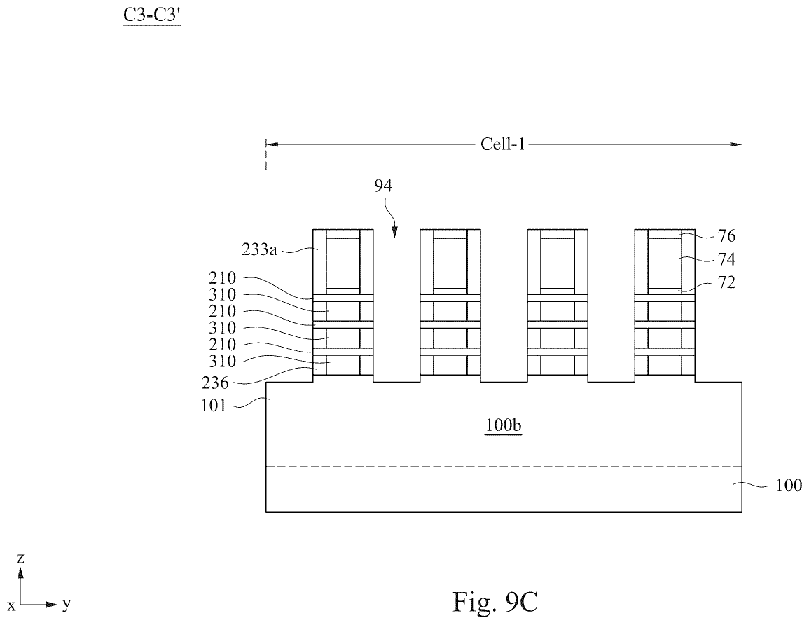

Reference is made to FIGS. 9A-9C. Source/drain recesses 94 can be formed in the semiconductor sheets 310 and the channel layers 210. In some embodiments, the source/drain recesses 94 extend through the semiconductor sheets 310 and the channel layers 210 and into the fin strips 101. In some embodiments, the fin strips 101 may be etched such that bottom surfaces of the source/drain recesses 94 are disposed below the top surfaces of the STI structures 251. The source/drain recesses 94 may be formed by etching the semiconductor sheets 310 and the channel layers 210 using an anisotropic etching processes, such as a RIE, a NBE, or the like. The layers 233a and the dummy gates 74 act as mask portions of the fin strips 101, the semiconductor sheets 310, and the channel layers 210 during the etching processes used to form the source/drain recesses 94. A single etch process may be used to etch each of the semiconductor sheets 310 and the channel layers 210, or multiple etch processes may be used to etch the semiconductor sheets 310 and the channel layers 210. Timed etch processes may be used to stop the etching of the source/drain recesses 94 after the source/drain recesses 94 reach a desired depth.

Subsequently, inner spacers 236 are formed on sidewalls of the remaining portions of the semiconductor sheets 310, e.g., those sidewalls exposed by the source/drain recesses 94. As will be subsequently described in greater detail, source/drain regions will be subsequently formed in the source/drain recesses 94, and the semiconductor sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the semiconductor sheets 310.

As an example to form the inner spacers 236, the source/drain recesses 94 can be laterally expanded. Specifically, portions of the sidewalls of the semiconductor sheets 310 exposed by the source/drain recesses 94 may be recessed. Although sidewalls of the semiconductor sheets 310 are illustrated as being straight, the sidewalls may be concave or convex. The sidewalls may be recessed by any acceptable etching process, such as one that is selective to the material of the semiconductor sheets 310 (e.g., selectively etches the material of the semiconductor sheets 310 at a faster rate than the material of the channel layers 210). The etching may be isotropic. For example, when the channel layers 210 are formed of silicon and the semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the semiconductor sheets 310.

The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the layer 233a. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the layer 233a, the outer sidewalls of the inner spacers 236 may extend beyond or be recessed from the sidewalls of the layer 233a. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

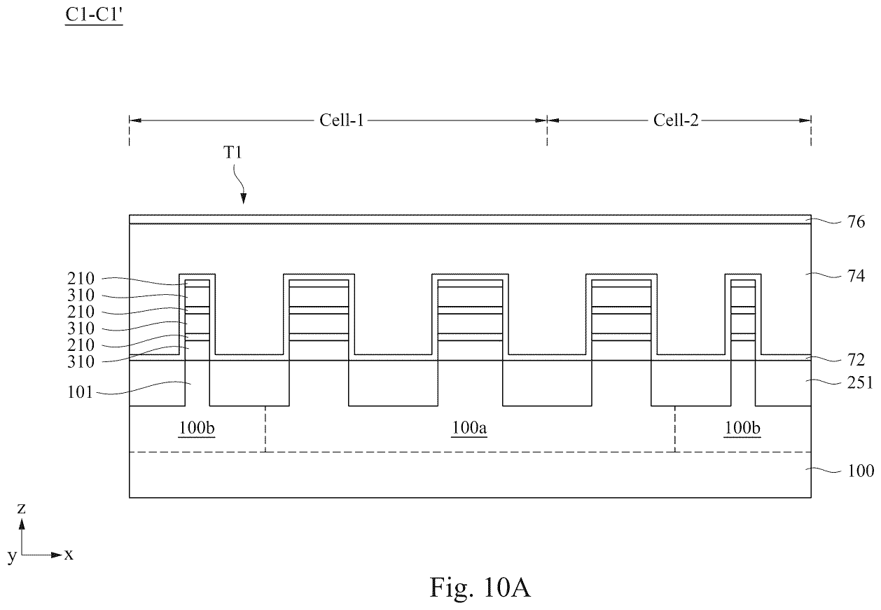

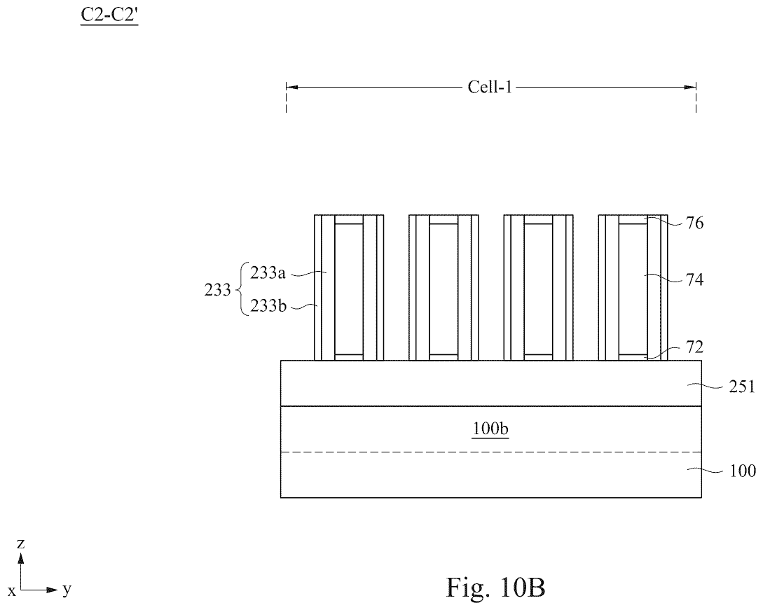

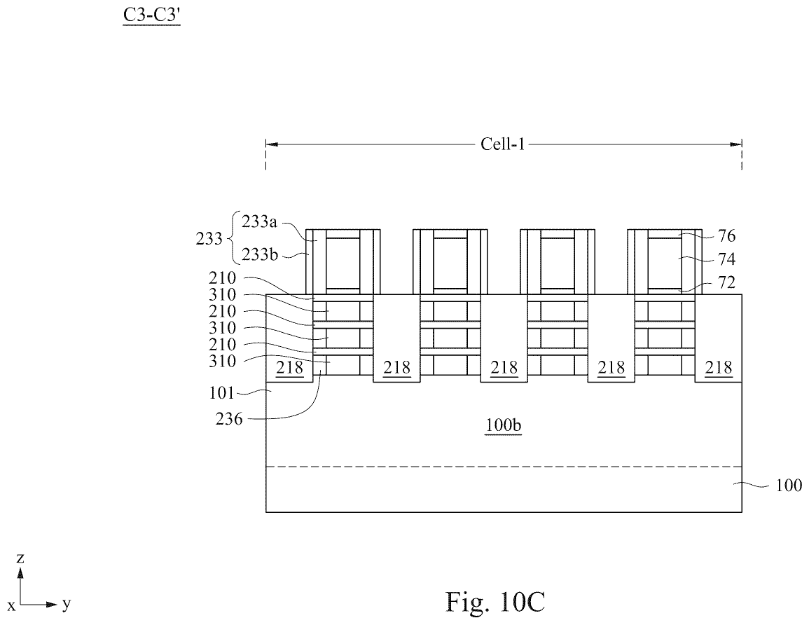

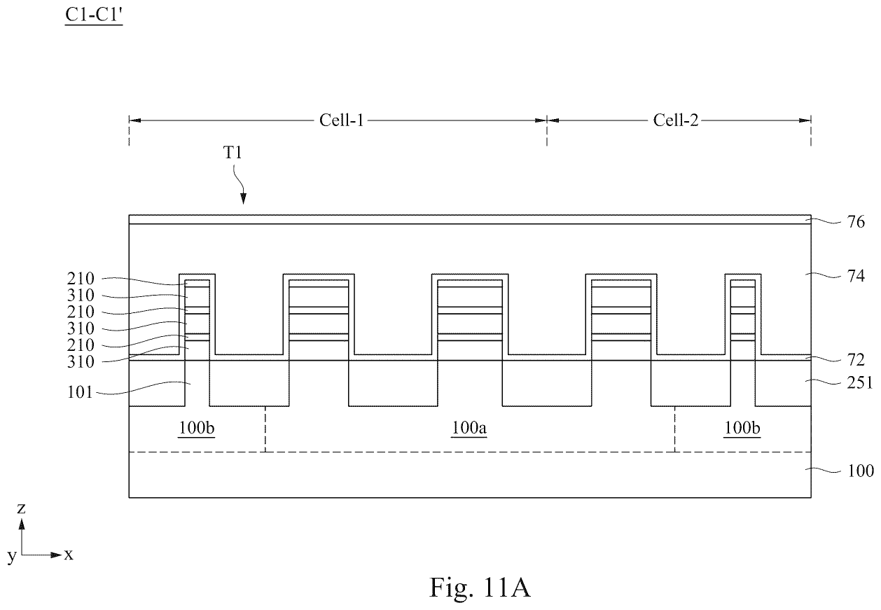

Reference is made to FIGS. 10A-10C. Epitaxial source/drain regions 218 can be formed in the source/drain recesses 94, such that each dummy gate 74 (and corresponding channel layers) is disposed between respective adjacent pairs of the epitaxial source/drain regions 218. Subsequently, the layer 233b can be formed on the layer 233a, such that the layers 233a and 233b can be collectively referred to as the gate spacer 233 as top spacer. In some embodiments, the gate spacers 233 and the inner spacers 236 are used to separate the epitaxial source/drain regions 218 from, respectively, the dummy gates 74 and the semiconductor sheets 310 by an appropriate lateral distance so that the epitaxial source/drain regions 218 do not short out with subsequently formed gates of the resulting nano-FETs.

In some embodiments, the gate spacer 233 may have a lateral dimension in a range from about 4 nm to about 12 nm. In some embodiments, the layer 233b may include multiple dielectric material and selected from a group consist of SiO₂, Si₃N₄, carbon doped oxide, nitrogen doped oxide, porous oxide, air gap, or combinations thereof. The layer 233b may be formed by conformally depositing one or more dielectric material(s) and subsequently etching the dielectric material(s). Acceptable dielectric materials may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the layer 233a, and thus the layer 233b is formed.

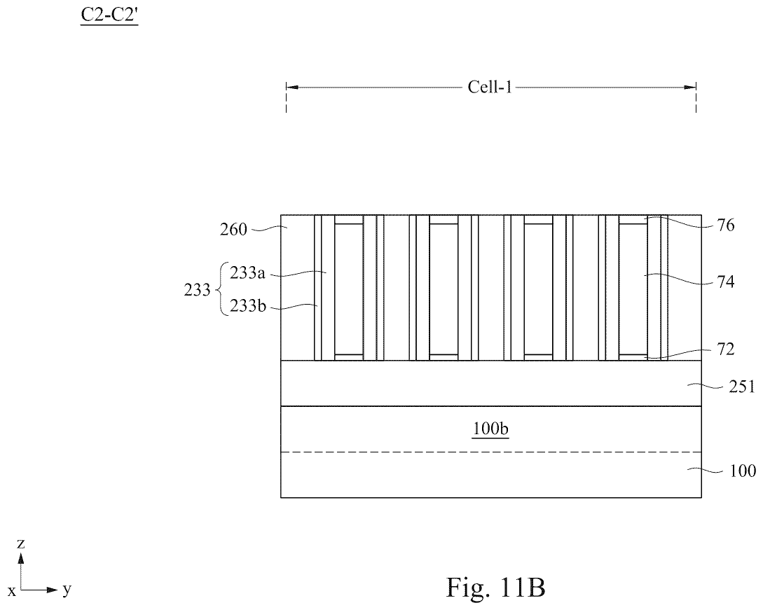

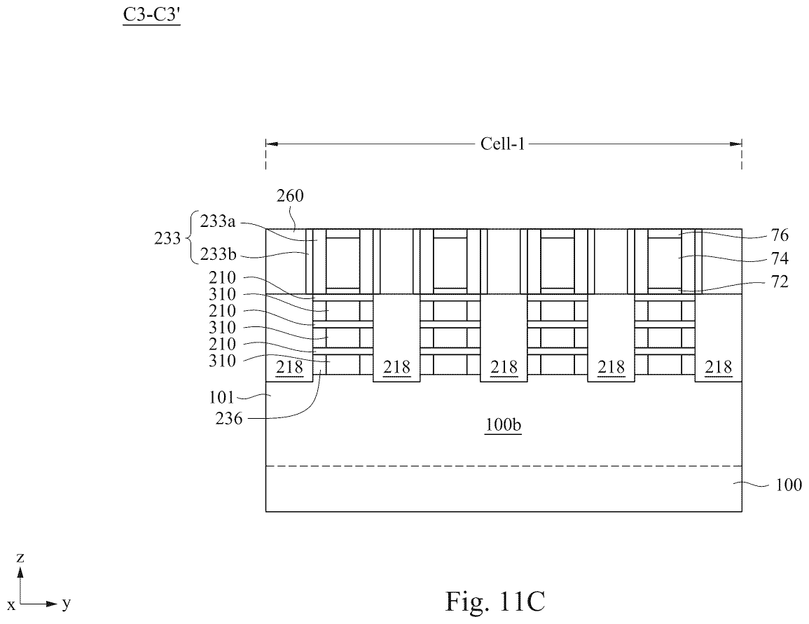

Reference is made to FIGS. 11A-11C. An inter-layer dielectric (ILD) layer 260 can be deposited over the epitaxial source/drain regions 218, the gate spacers 233, and the masks 76 (if present)/the dummy gates 74. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. In some embodiments, the ILD layers 260 and 262 may be made of an oxide, nitride, the like, or combinations thereof. Other insulation materials formed by any acceptable process may be used. In some embodiments, a contact etch stop layer (CESL) is formed between the ILD layer 260 and the epitaxial source/drain regions 218, the gate spacers 233, and the masks 76 (if present)/the dummy gates 74. The CESL may be formed of a dielectric material, such as silicon nitride, silicon oxide, silicon oxynitride, or the like, having a high etching selectivity from the etching of the ILD 260. The CESL may be formed by an any suitable method, such as CVD, ALD, or the like.

Subsequently, a removal process is performed to level the top surfaces of the ILD layer 260 with the top surfaces of the masks 76 (if present)/the dummy gates 74. In some embodiments, a planarization process such as a chemical mechanical polish (CMP), an etch-back process, combinations thereof, or the like may be utilized. After the planarization process, the top surfaces of the gate spacers 233, the ILD layer 260, the CESL, and the masks 76 (if present)/the dummy gates 74 are coplanar (within process variations). Accordingly, the top surfaces of the masks 76 (if present)/the dummy gates 74 can be exposed through the ILD layer 260. In some embodiments, the masks 76 remain, and the planarization process levels the top surface of the ILD layer 260 with the top surfaces of the masks 76.

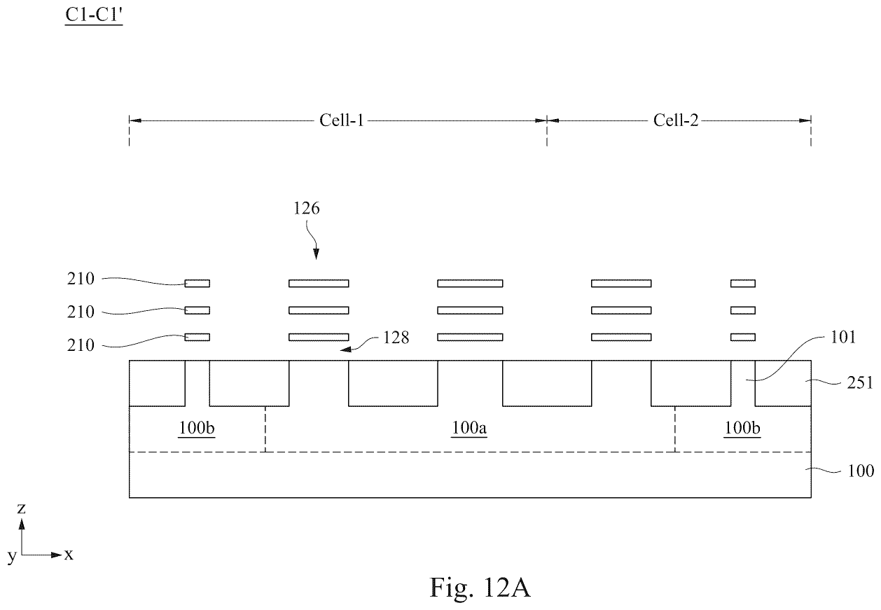

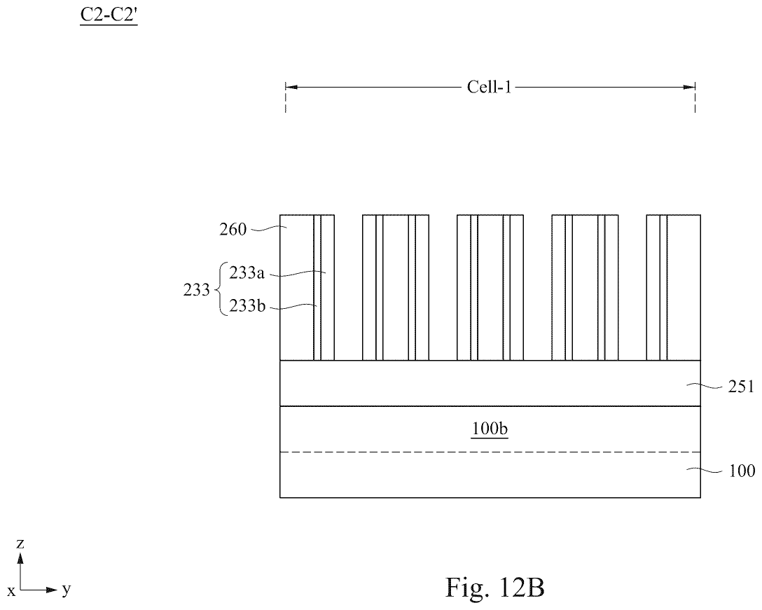

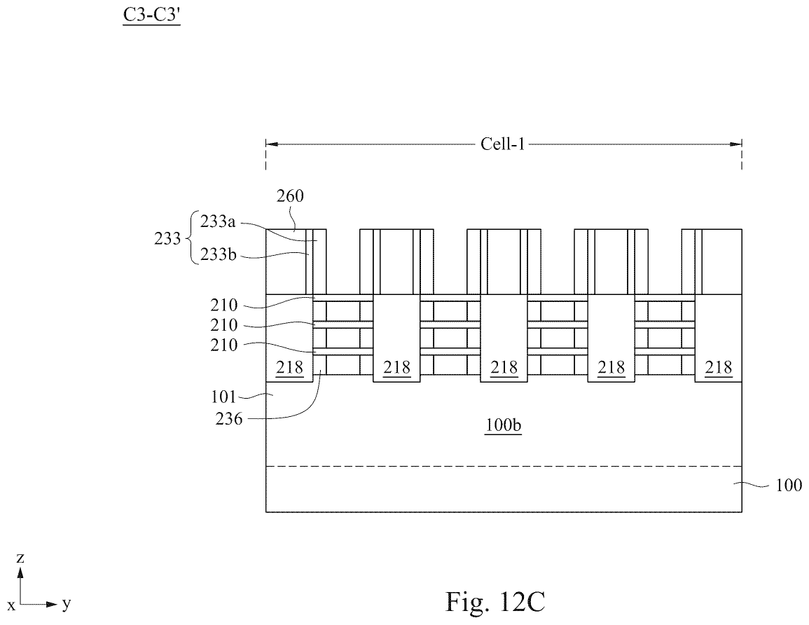

Reference is made to FIGS. 12A-12C. The masks 76 (if present) and the dummy gates 74 are removed in an etching process, so that recesses 126 are formed. Portions of the dummy dielectrics 72 can also be removed. In some embodiments, the dummy gates 74 are removed by an anisotropic dry etch process. For example, the etching process may include a dry etch process using reaction gas(es) that selectively etch the dummy gates 74 at a faster rate than the ILD layer 260 and the gate spacers 233. During the removal, the dummy dielectrics 72 may be used as etch stop layers when the dummy gates 74 are etched. The dummy dielectrics 72 are then removed. Each recess 126 can expose and/or overlies portions of the channel layers 210 disposed between adjacent pairs of the epitaxial source/drain regions 218.

The remaining portions of the semiconductor sheets 310 are then removed to expand the recesses 126, such that openings 128 are formed in regions between the channel layers 210. The remaining portions of the semiconductor sheets 310 can be removed by any acceptable etching process that selectively etches the material of the semiconductor sheets 310 at a faster rate than the material of the channel layers 210. The etching may be isotropic. For example, when the semiconductor sheets 310 are formed of silicon germanium and the channel layers 210 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the channel layers 210. In some embodiments, the removing of the remaining portions of the semiconductor sheets 310 can be interchangeably referred to as a channel releasing process. The channel layers 210 can be interchangeably referred to as a vertically stacked multiple channels (sheets) and may have a vertically sheet pitch within a range of from about 10 nm to about 30 nm. In some embodiments, the channel layers 210 may have a thickness within a range from about 4 nm to about 10 nm. In some embodiments, the vertically sheet pitch of the between adjacent two of the channel layers 210 may be within a range from about 6 to about 20 nm.

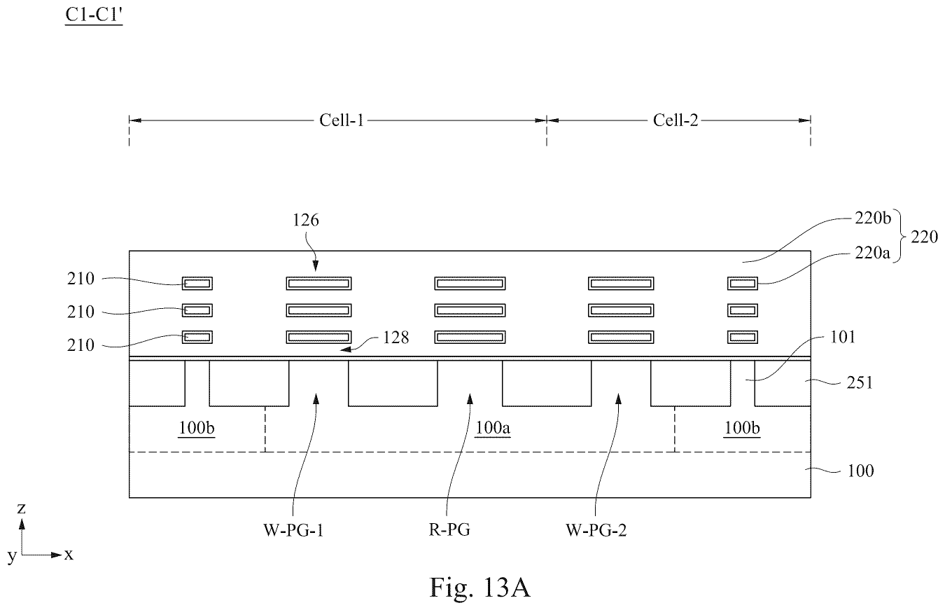

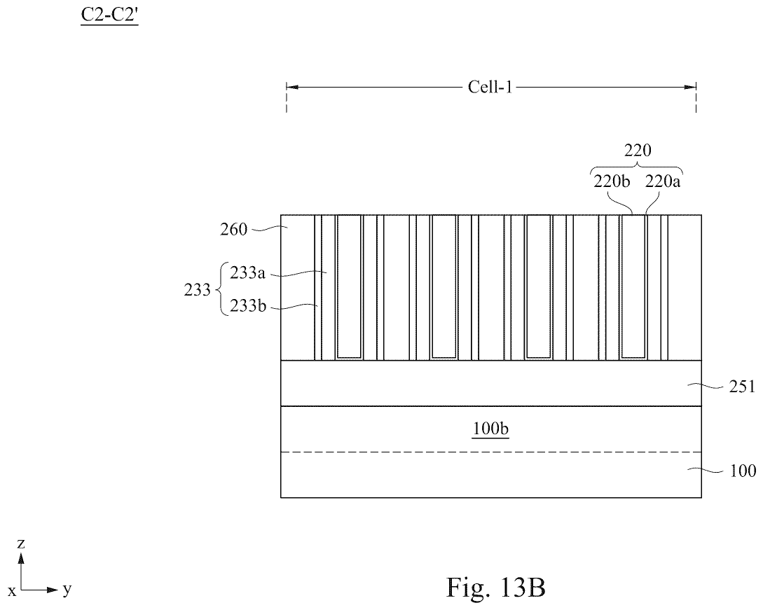

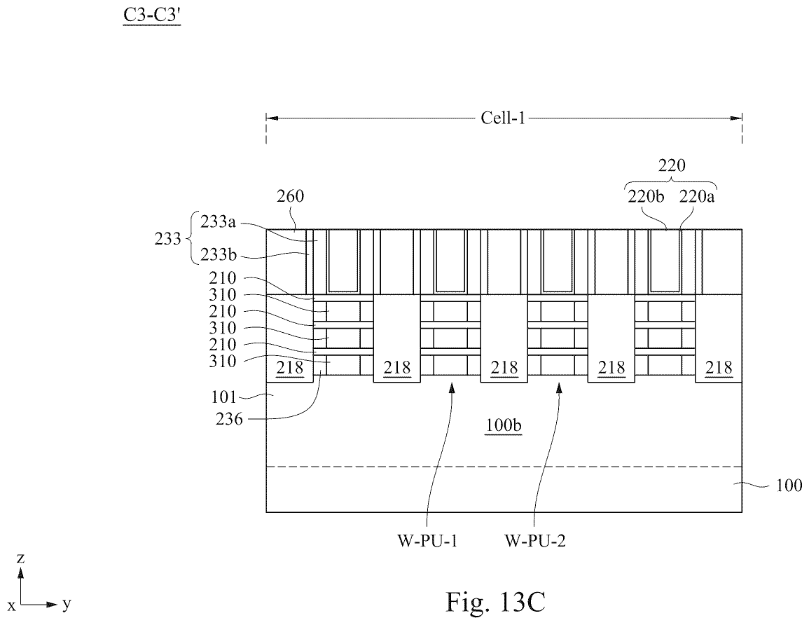

Reference is made to FIGS. 13A-13C. Gate structures 220 are formed to wrap around the channel layers 210. The gate structure 220 can include a gate dielectric layer 220a formed in the recesses 126 and a gate electrode layer 220b formed on the gate dielectric layer 220a. The gate dielectric layer 220a and the gate electrode layers 220b are layers for replacement gates, and each wrap around all (e.g., four) sides of the second channel layer 210. Specifically, the gate dielectric layer 220a is disposed on the sidewalls and/or the top surfaces of the fin strips 101; on the top surfaces, the sidewalls, and the bottom surfaces of the channel layers 210; and on the sidewalls of the gate spacers 233. Subsequently, the gate electrode layer 220b is formed over the gate dielectric layer 220a. In some embodiments, material and manufacturing method of the gate dielectric layer 220a and the gate electrode layer 220b are substantially the same as that shown in FIGS. 5A-5C, and the related detailed descriptions may refer to the foregoing paragraphs, and are not described again herein for the purpose of simplicity and clarity.

Subsequently, a removal process is performed to remove the excess portions of the materials of the gate dielectric layer 220a and the gate electrode layers 220b, which excess portions are over the top surfaces of the ILD layer 260 and the gate spacers 233, thereby forming gate dielectric layer 220a and gate electrode layers 220b. In some embodiments, a planarization process such as a chemical mechanical polish (CMP), an etch-back process, combinations thereof, or the like may be utilized. The gate dielectric layer 220a, when planarized, has portions left in the recesses 126. The gate electrode layers 220b, when planarized, have portions left in the recesses 126. The top surfaces of the gate spacers 233; the CESL (not shown); the ILD layer 260; the gate dielectric layer 220a, and the gate electrodes are coplanar (within process variations). The gate dielectric layer 220a and the gate electrode layers 220b form replacement gates of the resulting nano-FETs. In some embodiments, the gate electrode layers 220b each have a gate length in a range from about 6 nm to about 20 nm.

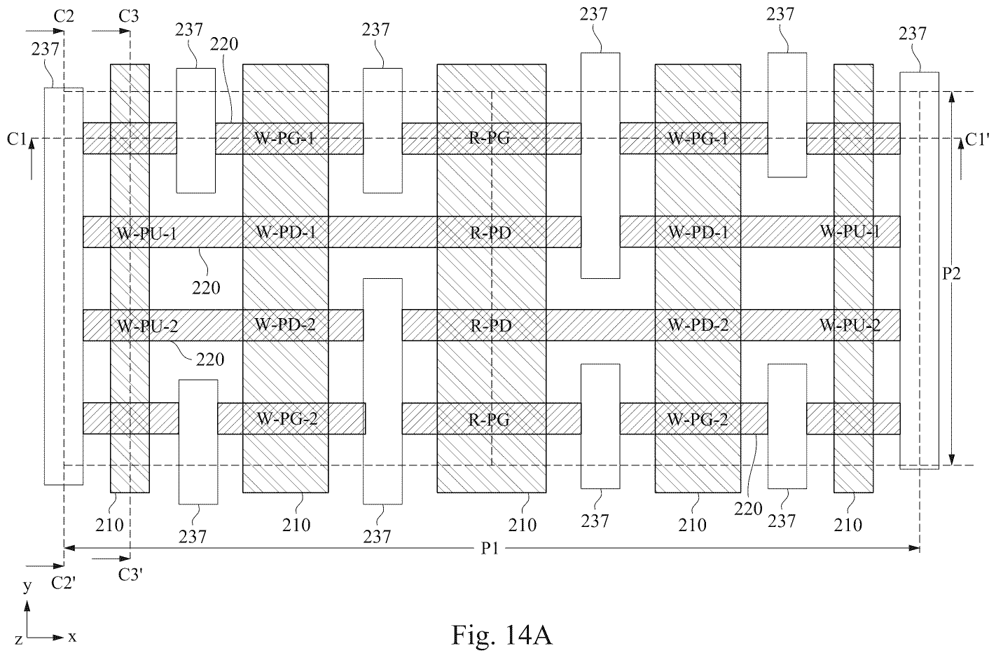

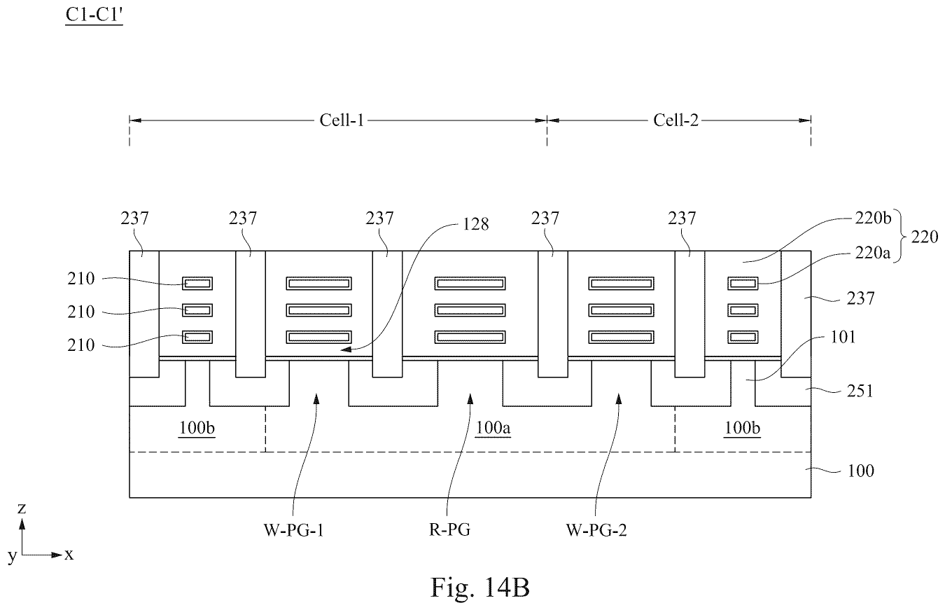

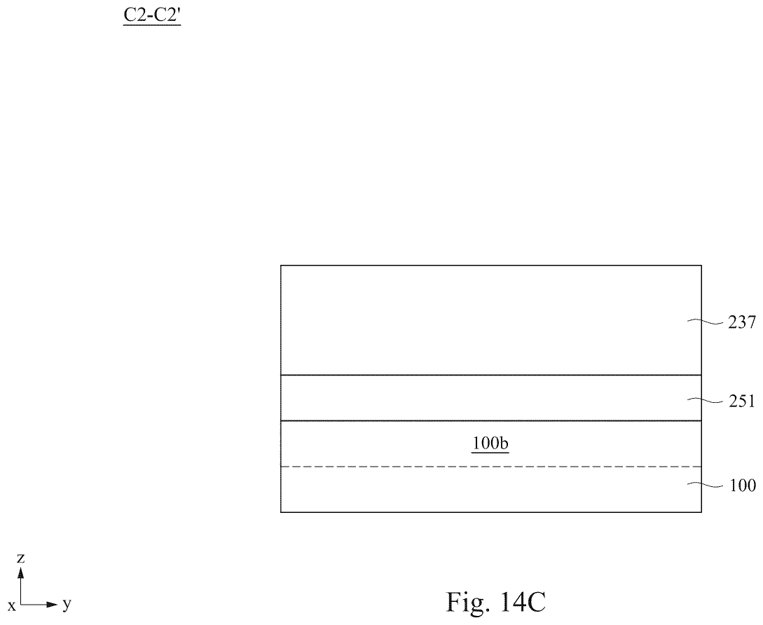

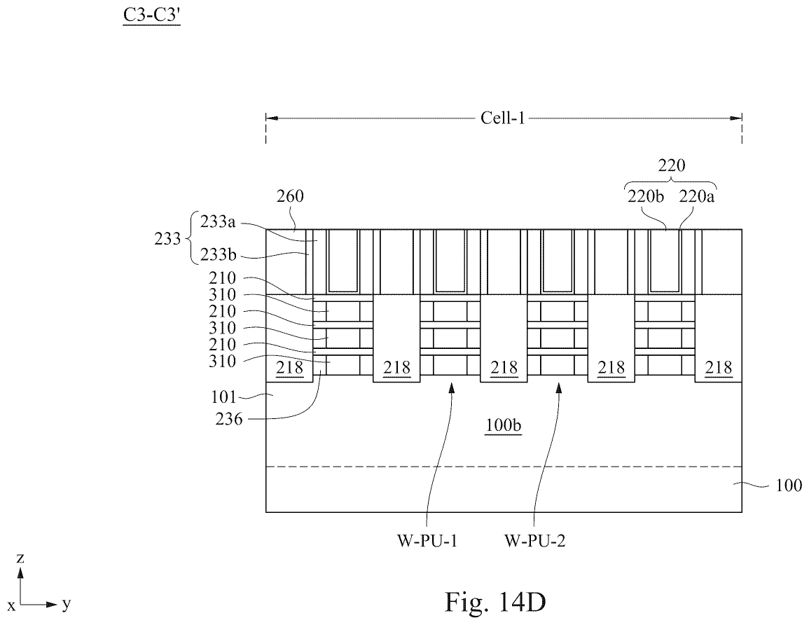

Reference is made to FIGS. 14A-14D. The gate end dielectric structure 237 can be formed as a gate-cut structure for the gate structure. In some embodiments, the gate end dielectric structures 237 can formed by a cut metal gate (CMG) process. Specifically, portions of the gate electrode layers 220b and the gate dielectric layers 220a are removed to reappear portions of the gate trenches with the gate spacers 215 as their sidewalls. The portions of the gate electrode layers 220b and the gate dielectric layer 220a may be removed by dry etching, wet etching, or a combination of dry and wet etching. For example, a wet etching process may include exposure to a hydroxide containing solution (e.g., ammonium hydroxide), deionized water, and/or other suitable etchant solutions. Subsequently, a dielectric material is deposited into the gate trenches, followed by a planarization process to remove excess portions of the dielectric material. The remaining dielectric material forms the gate end dielectric structures 237. In some embodiment, a top surface of the gate end dielectric structure 237 can be level with a top surface of the gate structure 220. In some embodiments, the deposition of the dielectric material of the gate end dielectric structures 237 is performed using a conformal deposition process such as ALD, which may be PEALD, thermal ALD, or the like. In some embodiments, material of the gate end dielectric structures 237 is substantially the same as that shown in FIGS. 5A-5C, and the related detailed descriptions may refer to the foregoing paragraphs, and are not described again herein for the purpose of simplicity and clarity.

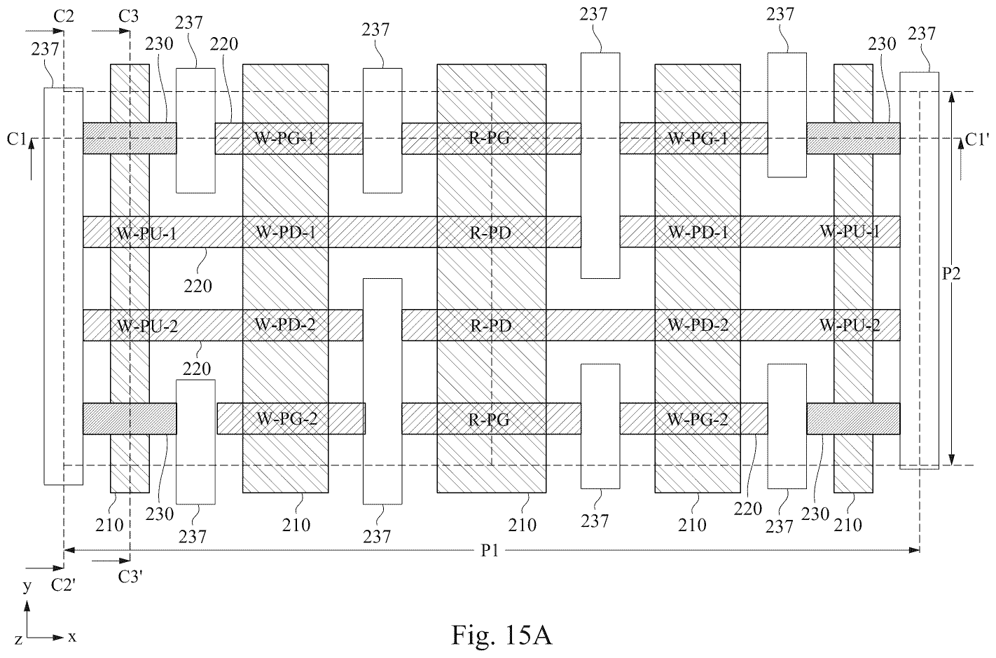

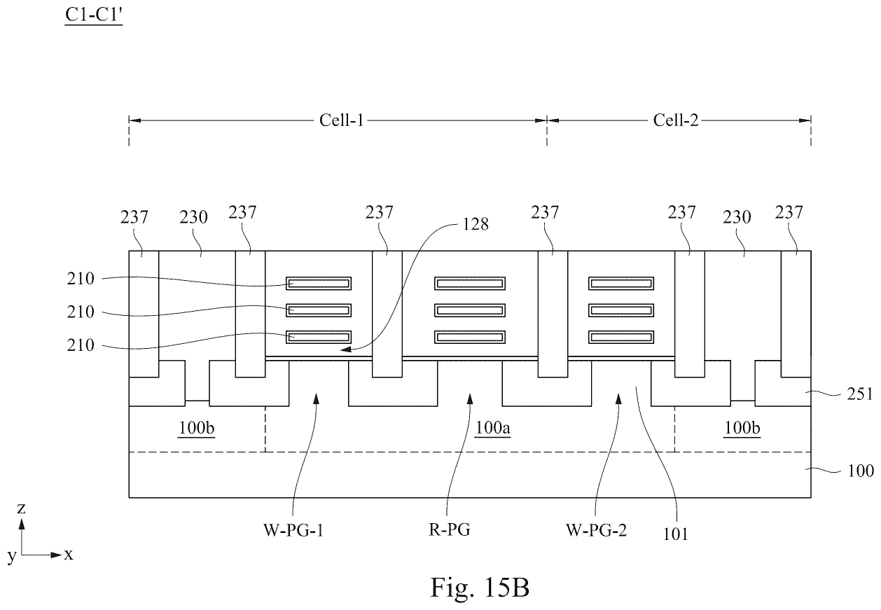

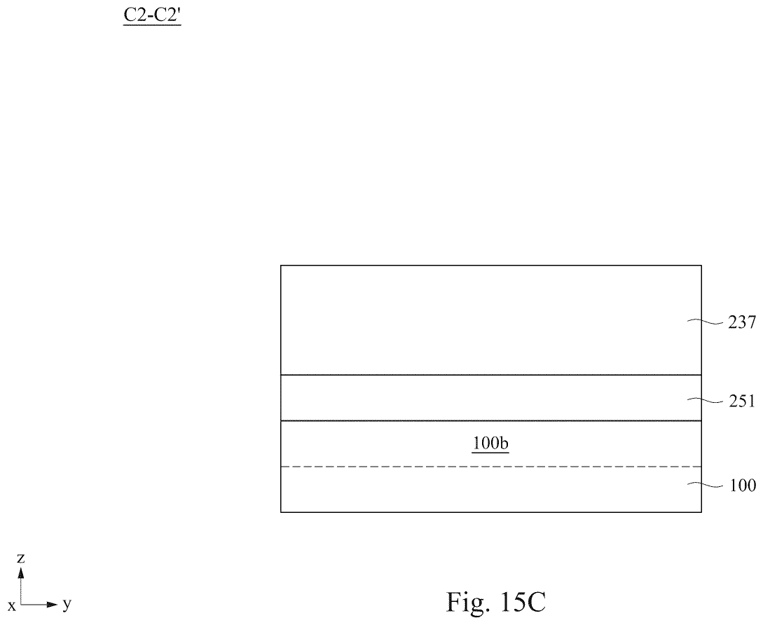

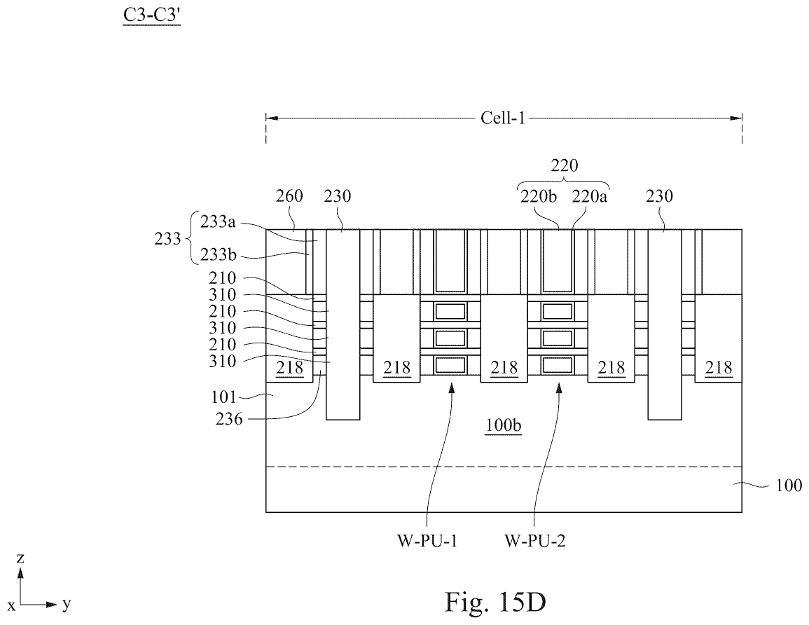

Reference is made to FIGS. 15A-15D. Some of the gate structures 220 are replaced by the dielectric gates 230. Specifically, some of the gate structures 220 are removed to form an isolation region separating the source/drain regions of neighboring semiconductor devices from each other. The isolation region may be formed by using an etching process. In the etching process, the gate electrode layer 220b and the gate dielectric layer 220a can be etched anisotropically, until underlying fin strip 101 is exposed. In some embodiments, the etching may be stopped on the STI structure 251. In some embodiments, the fin strip 101 is then etched, and the etching continues down into the underlying substrate 100. Subsequently, a dielectric material is filled in the isolation region (i.e., spaces originally occupied by the gate structure 220. In some embodiments, the dielectric material can be formed by, such as chemical vapor deposition (CVD), physical vapor deposition (PVD), atomic layer deposition (ALD), high density plasma CVD (HDPCVD), metal organic CVD (MOCVD), or plasma enhanced CVD (PECVD). Subsequently, a planarization process such as a chemical mechanical polish (CMP), an etch-back process, combinations thereof, or the like may be utilized on the dielectric material until the gate spacers 233 is exposed, such that the dielectric gate 230 can be formed. In some embodiments, material of the dielectric gate 230 is substantially the same as that shown in FIGS. 5A-5C, and the related detailed descriptions may refer to the foregoing paragraphs, and are not described again herein for the purpose of simplicity and clarity.

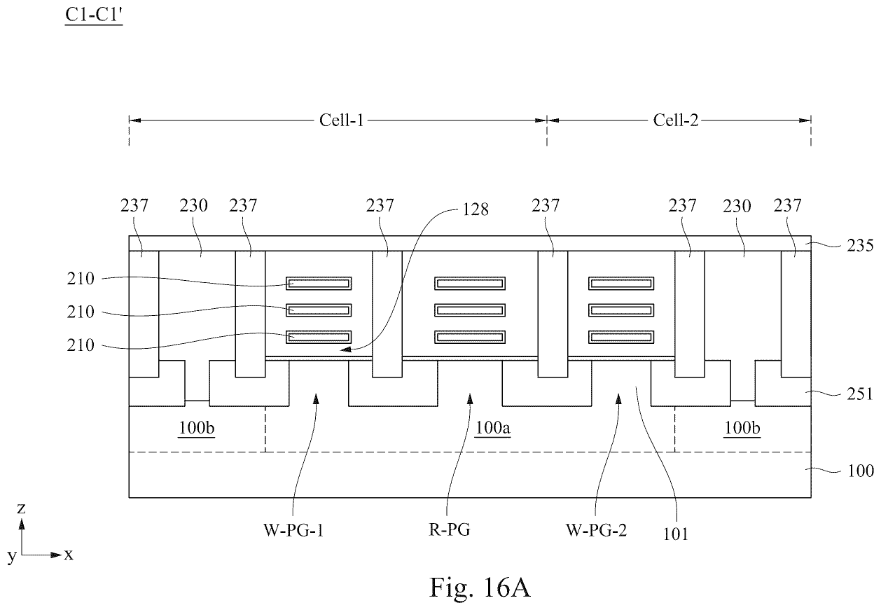

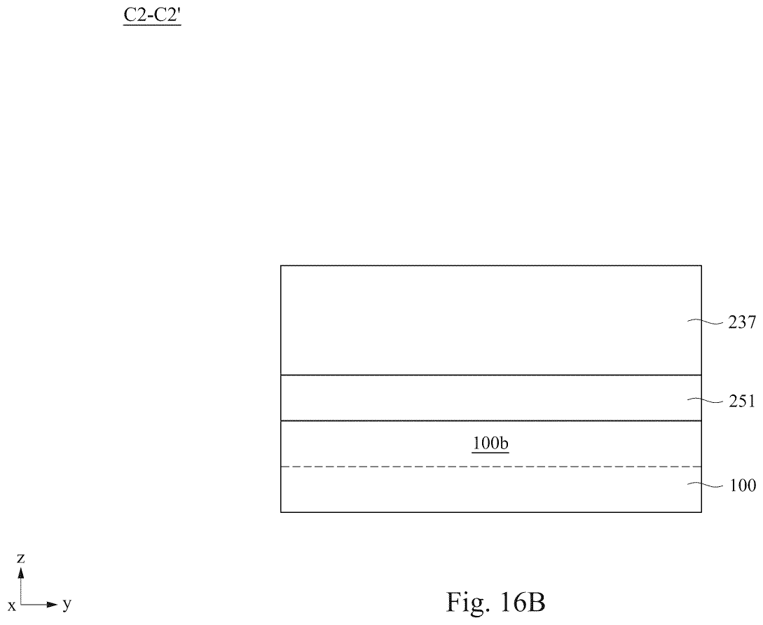

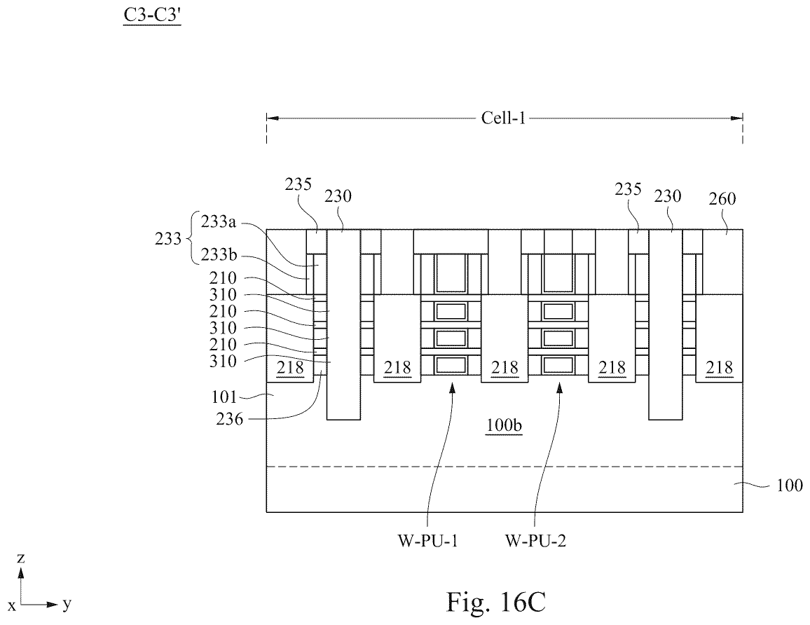

Reference is made to FIGS. 16A-16C. An etch back process is performed on the gate structure 220 and the gate spacer 233 to form the hard mask layer 235. Specifically, the etch back process may include a bias plasma etching step. The bias plasma etching step may be performed to remove portions of the gate structure 220 and the gate spacer 233. Portions of the gate trenches may reappear with shallower depth. Top surfaces of the gate structure 220 and the gate spacer 233 may be no longer level with the ILD layer 260. In some embodiments, the bias plasma etching step may use a gas mixture of Cl₂, O₂, BCl₃, and Ar with a bias in a range from about 25V to about 1200V.

Subsequently, the hard mask layer 235 is formed over the gate structure 220 and the gate spacer 233 using, for example, a deposition process to deposit a dielectric material over the substrate 100, followed by a CMP process to remove excess dielectric material above the ILD layer 260. The hard mask layer 235 has different etch selectivity than the ILD layer 260, so as to selective etch back the hard mask layer 235 rather than the ILD layer 260. By way of example, if the hard mask layer 235 is made of silicon nitride, the ILD layer 260 may be made of a dielectric material different from silicon nitride. If the hard mask layer 235 is made of silicon carbide (SIC), the ILD layer 260 may be made of a dielectric material different from silicon carbide. Therefore, the hard mask layer 235 can be used to define self-aligned gate contact region and thus referred to as a self-aligned contact (SAC) structure or a SAC layer. In some embodiments, the hard mask layer 235 may have a thickness in a range from about 2 nm to about 60 nm, such as about 2, 5, 10, 15, 20, 25, 30, 35, 40, 45, 50, 55, or 60 nm. In some embodiments, material of the hard mask layer 235 is substantially the same as that shown in FIGS. 5A-5C, and the related detailed descriptions may refer to the foregoing paragraphs, and are not described again herein for the purpose of simplicity and clarity.

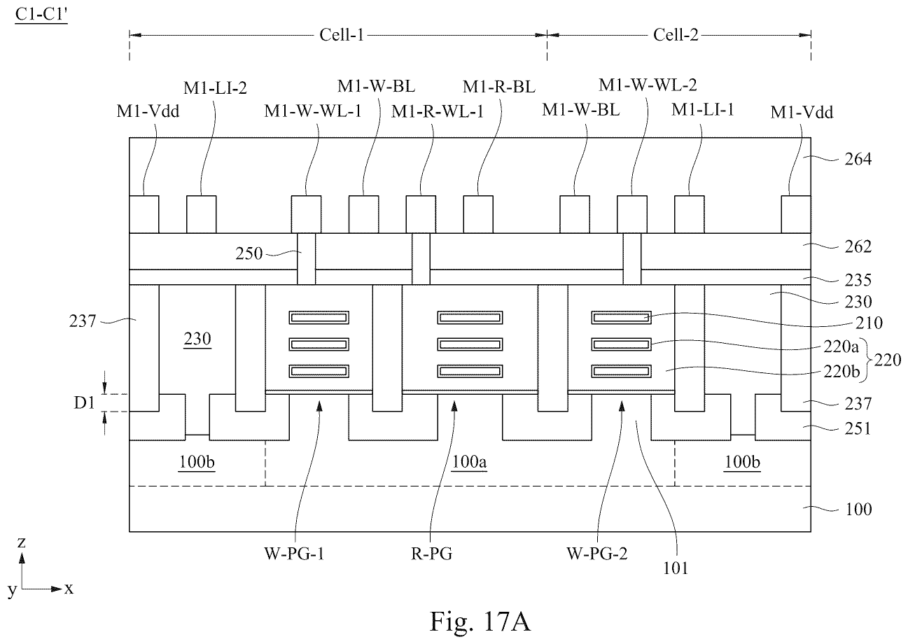

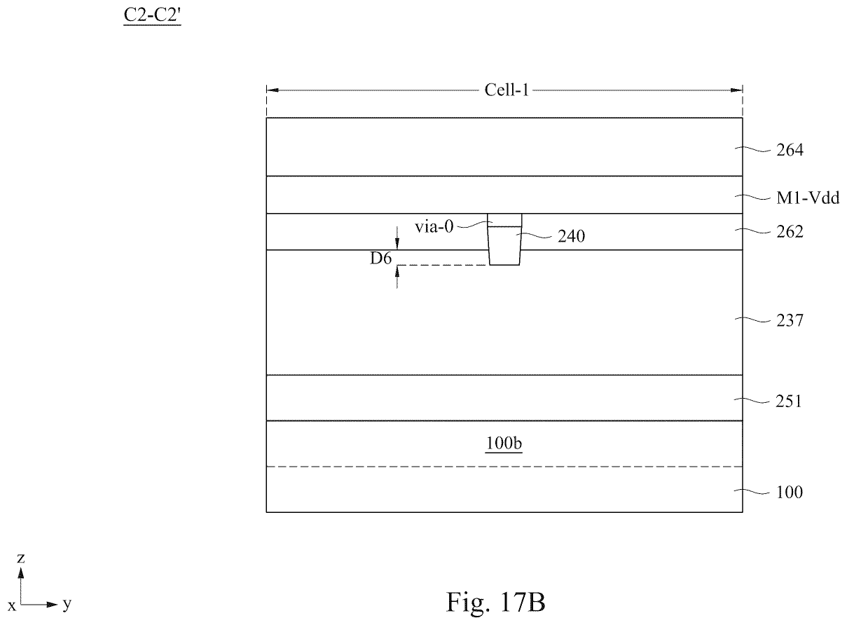

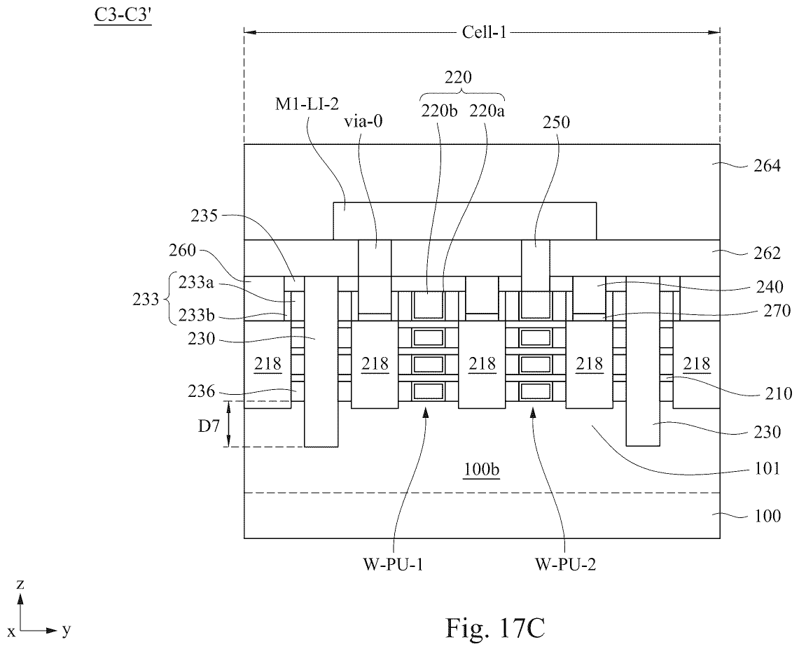

Reference is made to FIGS. 17A-17C. In some embodiments, source/drain contacts 240 formed subsequently are formed in the ILD layer 260 by a self-aligned contact process using the hard mask layer 235 as a contact etch protection layer. Subsequently, an ILD layer 262 may be deposited over the ILD layers 260, the hard mask layers 235, the source/drain contacts 240, the gate end dielectric structures 237, and the dielectric gates 230. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, source/drain via-0 may be formed in the ILD layer 262 and on the corresponding source/drain contact 240, and a gate via 250 may be formed to pass through the ILD layer 262 and the hard mask layer 235 and land on the gate structure 220, In some embodiments, the source/drain contacts 240, the source/drain via-0, and/or the gate via 250 may include a metal-containing material such as titanium nitride, titanium oxide, tungsten, cobalt, ruthenium, aluminum, copper, combinations thereof, multi-layers thereof, or the like.

Subsequently, an interconnect structure including metal lines and vias can be formed over the ILD layer 262 to electrically connect to the corresponding gate vias 250 or the corresponding source/drain vias via-0. The metal lines can include the power supply voltage lines M1-Vdd, the read bit-line M1-R-BL, the local connection lines M1-L1-1 and M1-L1-2, the read word-lines M2-R-WL-1 and M2-R-WL-2, the power supply voltage line M3-Vss, the write bit-line M3-W-BL, the write bit-line-bar M3-W-BLB, the power supply voltage line M4-Vss, and the write word-lines M4-W-WL-1 and M4-W-WL-2. The metal vias can include the interconnect vias via-1, via-2, and via-3. In some embodiments, materials of the metal lines and vias may be made of a conductive material, such as Cu, Co, Ru, Pt, Al, W, Ti, TaN, TiN, or any combinations thereof. Also included in the interconnect structure is an inter-metal dielectric (IMD) layer 264 (see FIGS. 5A-5C). The IMD layer 264 may provide electrical insulation as well as structural support for the various features of the interconnect structure. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 264 may be made of an oxide, nitride, the like, or combinations thereof.

As an example to form the conductive lines in the interconnect structure, trenches/openings for the conductive lines are formed through the IMD layer. The trenches/openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the IMD layer. The remaining liner and conductive material form the conductive lines in the trenches/openings. The conductive lines may be formed in distinct processes, or may be formed in the same process. In some embodiments, material and manufacturing method of the conductive lines (not shown) in other metallization layers are substantially the same as those of the conductive line in the first metallization layer as shown in FIGS. 17A-17C, and the related detailed descriptions may refer to the foregoing paragraphs, and are not described again herein for the purpose of simplicity and clarity and does not in itself dictate a relationship between the various embodiments and/or configurations discussed.

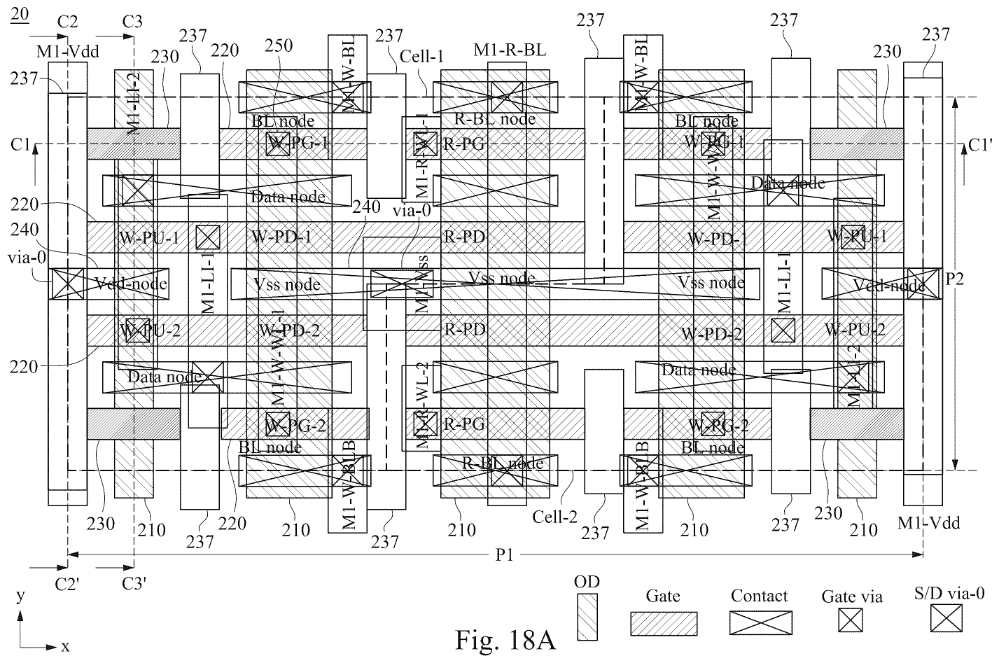

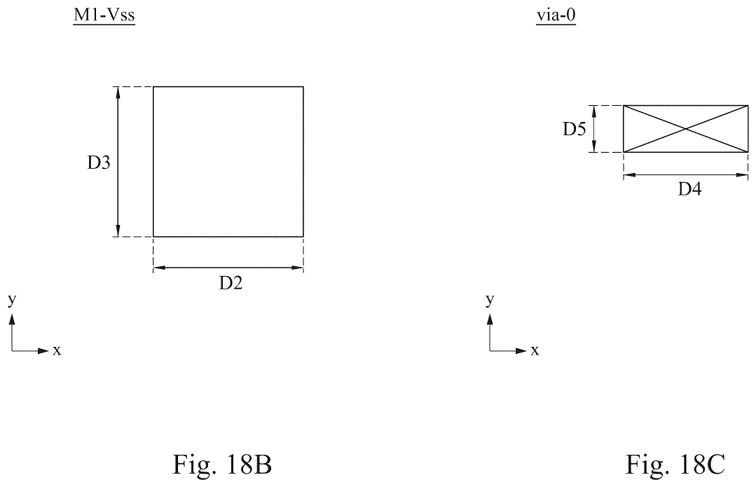

Reference is made to FIGS. 18A-18C. FIG. 18A illustrates a cell array layout diagram of a two-port SRAM circuit in accordance with some embodiments of the present disclosure. FIGS. 18B and 18C illustrates the power supply voltage line landing pad M1-Vss at M1 level and the underlying interconnect via via-0 in FIG. 18A in accordance with some embodiments of the present disclosure. While FIGS. 18A-18C illustrate embodiments of a semiconductor structure 20 with a different power supply voltage line landing pad configuration and a different underlying interconnect via configuration than the semiconductor structure 10 as shown in FIGS. 3A-17C, the present disclosure may repeat reference numerals and/or letters in the various examples. This repetition is for the purpose of simplicity and clarity and does not in itself dictate a relationship between the various embodiments and/or configurations discussed.

As shown in FIGS. 18A-18C, the power supply voltage line landing pad M1-Vss at M1 level has a greater top view area than that shown in FIG. 3A. Specifically, the power supply voltage line landing pad M1-Vss has a dimension D2 extending in the X-direction and a dimension D3 extending in the Y-direction. In some embodiments, a ratio of the dimension D3 to the dimension D2 can be in a range from about 0.5 to 2, such as about 0.5, 1, 1.5, or 2. In some embodiments, the dimension D2 of the power supply voltage line landing pad M1-Vss can extend across opposite longitudinal sides of the gate end dielectric structure 237. The interconnect via via-0 under the power supply voltage line landing pad M1-Vss can have a greater top view area than that shown in FIG. 3A. The interconnect via via-0 can extend along a lengthwise direction of the gate structure 220. Specifically, the interconnect via via-0 has a dimension D4 extending in the X-direction and a dimension D5 extending in the Y-direction. In some embodiments, a ratio of the dimension D4 to the dimension D5 can be in a range from about 1.5 to 4, such as about 1.5, 2, 2.5, 3, 3.5, or 4. In some embodiments, the interconnect via via-0 can overlap the gate end dielectric structure 237. The increased areas of the power supply voltage line landing pad M1-Vss and the interconnect via via-0 can facilitate improved electrical connection between the power supply and the SRAM cells, ensuring a stable voltage supply across the device, for maintaining the reliable operation of the SRAM cells.

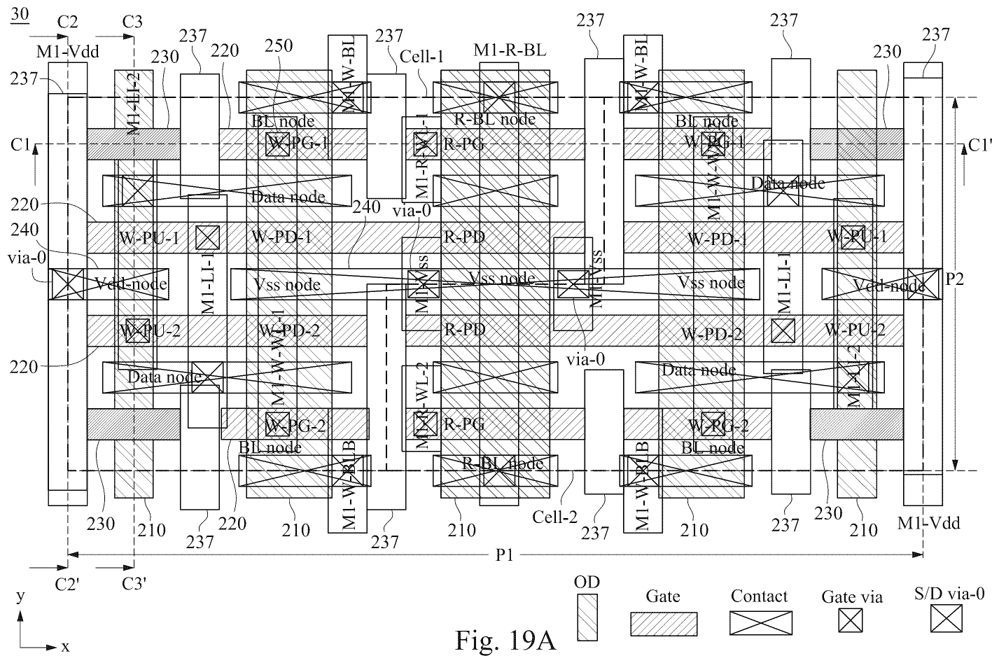

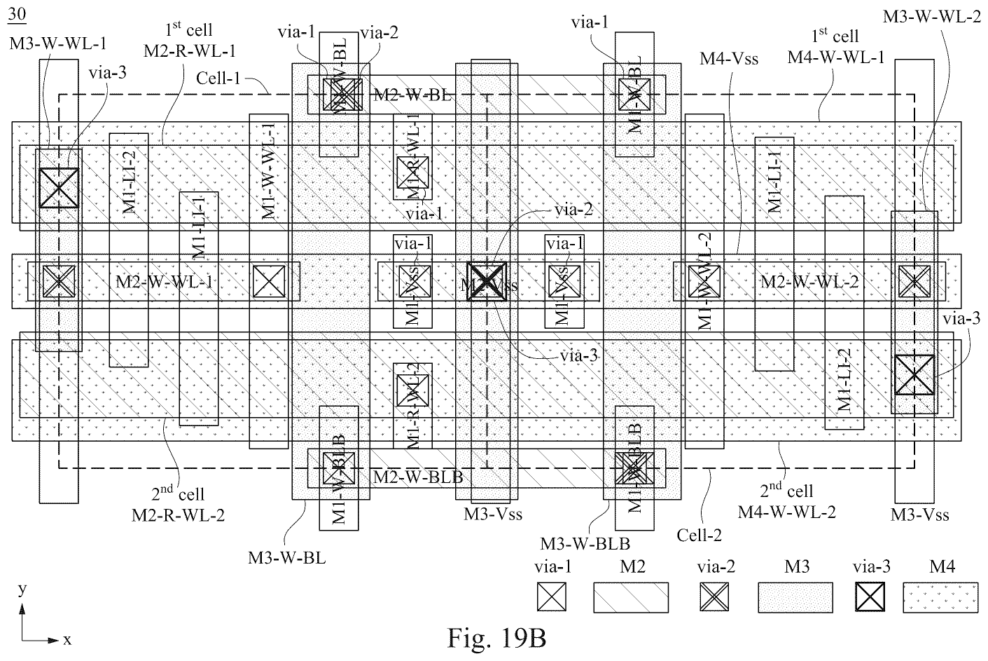

Reference is made to FIGS. 19A and 19B. FIGS. 19A and 19B illustrate cell array layout diagrams of a two-port SRAM circuit in accordance with some embodiments of the present disclosure. Specifically, FIG. 19A illustrates a cell array layout diagram of two two-port SRAM cells below a second interconnection layer (e.g., second metal layer) of a semiconductor structure 30. FIG. 19B illustrates a cell array layout diagram of two two-port SRAM cells from the first interconnection layer (e.g., first metal layer M1) to the fourth interconnection layer (e.g., first metal layer M4) of the semiconductor structure 30. While FIGS. 19A and 19B illustrate embodiments of the semiconductor structure 30 with a more power supply voltage line landing pad (e.g., two) than the semiconductor structure 10 as shown in FIGS. 3A-17C, the present disclosure may repeat reference numerals and/or letters in the various examples. This repetition is for the purpose of simplicity and clarity and does not in itself dictate a relationship between the various embodiments and/or configurations discussed.

As shown in FIGS. 19A and 19B, the semiconductor structure 30 can incorporate two power supply voltage line landing pads M1-Vss at the M1 level, each with corresponding interconnect vias via-0 positioned directly below them. This arrangement can not only double the connectivity for the power supply voltage line but also hint at a scalable model where the number of power supply voltage line landing pads M1-Vss can range from 3 to 10, such as 3, 4, 5, 6, 7, 8, 9, 10, catering to more complex or power-intensiveSRAM circuits. Moreover, the power supply voltage line landing pads M2-Vss at the M2 level in the X-direction can exhibit a longer length compared to that illustrated in FIG. 3D. In some embodiments, the increased number of power supply voltage line landing pads M1-Vss can facilitate improved power distribution across the SRAM cells, ensuring stable operation even under high load conditions. Additionally, the increased number of power supply voltage line landing pads M1-Vss can effectively decrease the resistance in the power delivery network, minimizing voltage drop and promoting consistent performance.

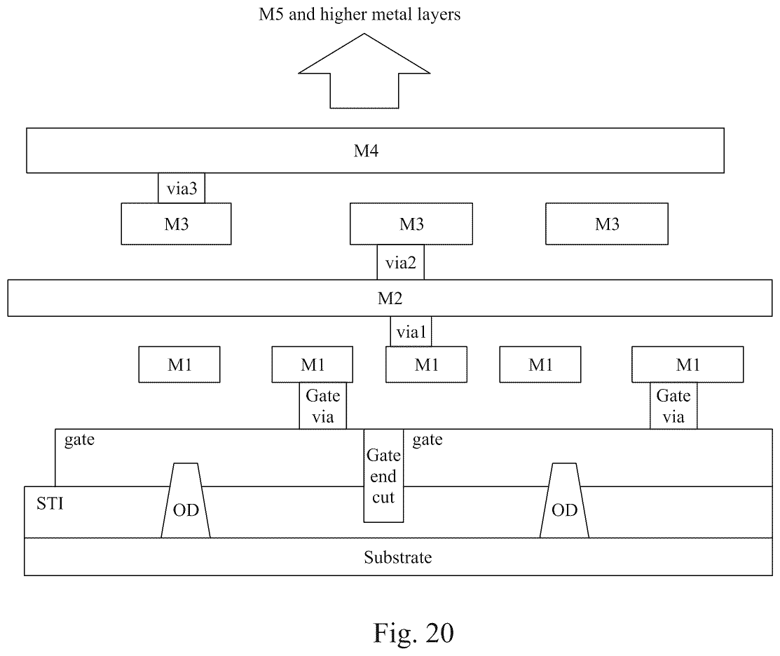

Reference is made to FIG. 20. FIG. 20 illustrates a schematic view of a semiconductor structure in accordance with some embodiments of the present disclosure. It is noted that FIG. 20 is schematically illustrated to show various levels of interconnect structure and transistors, and may not reflect the actual cross-sectional view of SRAM cell. The interconnect structure includes a contact level, an OD (wherein the term “OD” represents “active region”) level, via levels, such as gate via level, vial level, Via2 level, and Via3 level, and metal-layer levels, such as M1 level, M2 level, M3 level, and M4 level. Each of the illustrated levels includes one or more dielectric layers and the conductive features formed therein. The conductive features that are at the same level may have top surfaces substantially level to each other, bottom surfaces substantially level to each other, and may be formed simultaneously. The contact level may include gate vias (also referred to as contact plugs) for connecting gate electrodes of transistors (such as the illustrated exemplary transistors) to an overlying level such as the gate via level.

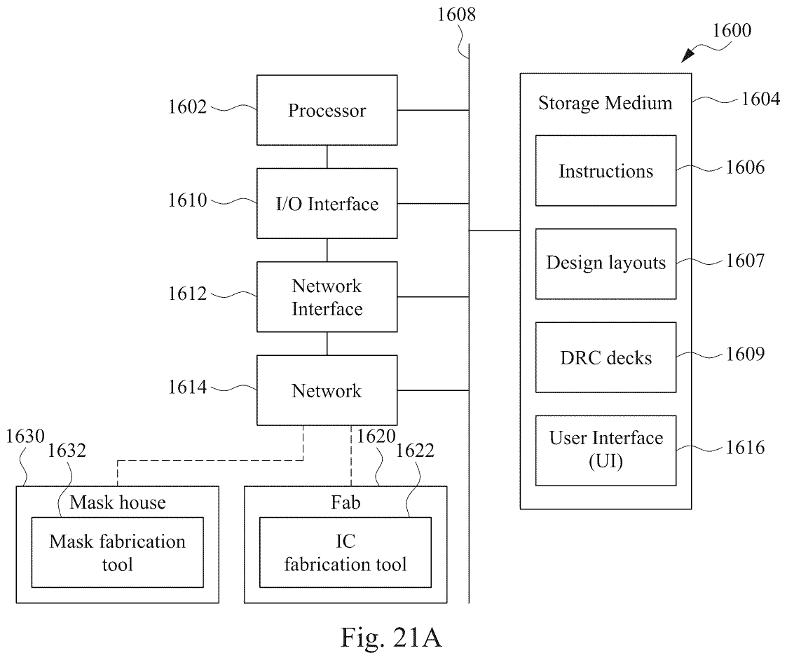

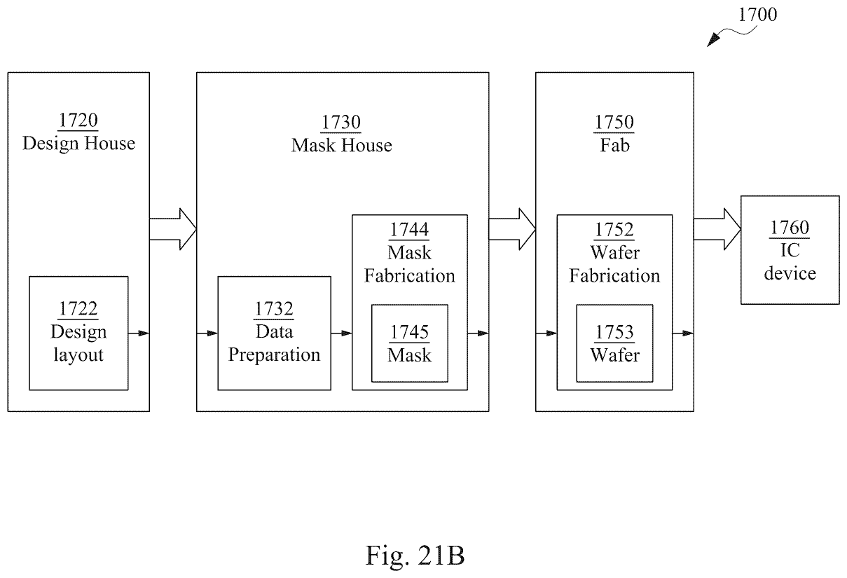

Reference is made to FIG. 21A. FIG. 21A is a schematic diagram of an electronic design automation (EDA) system 1600, in accordance with some embodiments. Methods described herein of generating design layouts, e.g., layouts of the integrated circuits of the semiconductor structure as discussed above, in accordance with one or more embodiments, are implementable, for example, using EDA system 1600, in accordance with some embodiments. At least integrated circuit is manufactured by a corresponding layout design similar to the corresponding integrated circuit. For brevity FIGS. 1-20 are described as corresponding integrated circuits, but in some embodiments, FIGS. 1-20 also correspond to layout designs with corresponding patterns with corresponding structures, and pattern relationships including alignment, lengths and widths, as well as configurations and layers of a corresponding layout design are similar to the structural relationships and configurations and layers of the corresponding integrated circuit, and similar detailed description will not be described for brevity. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts of the integrated circuits of the semiconductor structure as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 21A are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating integrated circuits of the semiconductor structure as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts of the integrated circuits of the semiconductor structure with resistor circuits as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a loadlock chamber installed at a different wall face of the transfer chamber.

Reference is made to FIG. 21B. FIG. 21B is a block diagram of an IC manufacturing system 1700, and an IC manufacturing flow associated therewith, in accordance with some embodiments. In some embodiments, based on one or more design layouts, e.g., layouts of the integrated circuits of the semiconductor structure as discussed above, one or more photomasks and one or more integrated circuits are fabricated using manufacturing system 1700.

In FIG. 21B, an IC manufacturing system 1700 includes entities, such as a design house 1720, a mask house 1730, and a Fab 1750, that interact with one another in the design, development, and manufacturing cycles and/or services related to manufacturing

ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts of the integrated circuits of the semiconductor structure as discussed above). Design layouts 1722 include various geometrical patterns designed for ICs 1760 (e.g., integrated circuits of the semiconductor structure as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout of the integrated circuit of the semiconductor structure as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 21B, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts of the integrated circuits of the semiconductor structure as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a metal line routing method to improve the functional density and operation performance on the IC structure. In the architecture of two-port SRAM cells, each cell can be designed with a distinct arrangement for its read and write pathways, utilizing a read bit-line along with a write bit-line and a write bit-line bar in two separate metallization layers for improved performance. When two adjacent two-port SRAM cells are grouped together in alignment with the word-line routing direction, they collectively can utilize a single read bit-line and a single pair of write bit-lines, allowing for a compact and efficient layout, supporting the operation of 16 transistors across 5 active regions. In some embodiments, the write pull-up transistors can be enhanced with a dielectric gate structure (e.g., common poly on diffusion edge (CPODE)) situated nearby to optimize their function. Furthermore, continuous gate end dielectric lines can incorporate at the two outer edges of the grouped cells adjacent to the write pull-up transistors. The gate end dielectric lines can extend across the entire height of the cell, functioning as a barrier to delineate the gate structures along the bit-line routing direction.

In some embodiments, a method includes forming a first static random access memory (SRAM) cell over a semiconductive substrate, the first SRAM cell comprising a first write port and a first read port; forming a second SRAM cell over the semiconductive substrate and adjacent to the first SRAM cell, the second SRAM cell comprising a second write port and a second read port; forming a first metal layer over the semiconductive substrate, the first metal layer comprising a read bit-line, wherein the first and second SRAM cell share the read bit-line; forming a second metal layer over the first metal layer, the second metal layer comprising a write bit-line and a write bit-line bar, wherein the first and second SRAM cell share the write bit-line and the write bit-line bar. In some embodiments, the method further includes forming a third metal layer over the first metal layer prior to forming the second metal layer, wherein the third metal layer comprises a first read word-line and a second read word-line, the first read word-line is electrically coupled to the first SRAM cell, and the second read word-line is electrically coupled to the second SRAM cell. In some embodiments, from a top view, the first and second SRAM cells are arranged along a lengthwise direction of the first read word-line. In some embodiments, the method further includes forming a fourth metal layer over the second metal layer, wherein the fourth metal layer comprises a first write word-line and a second write word-line, the first write word-line is electrically coupled to the first SRAM cell, and the second write word-line is electrically coupled to the second SRAM cell. In some embodiments, the first write port of the first SRAM cell comprises first and second write pull-up transistors, first and second write pull-down transistors, and first and second write pass-gate transistors, and the first read port of the first SRAM cell comprises a first read pull-down transistor and a first read pass-gate transistor. In some embodiments, the first and second write pull-down transistors and the first and second write pass-gate transistors of the first SRAM cell share a same channel pattern. In some embodiments, the first and second write pull-up transistors of the first SRAM cell share a same channel pattern. In some embodiments, the second read port of the second SRAM cell comprises a second read pull-down transistor and a second read pass-gate transistor, the first read pass-gate transistor and the first read pass-gate transistor of the first SRAM cell and the second read pass-gate transistor and the second read pass-gate transistor of the second SRAM cell share a same channel pattern. In some embodiments, the second write port of the second SRAM cell comprises third and fourth second write pull-up transistors, third and fourth write pull-down transistors, and third and fourth write pass-gate transistors. In some embodiments, the method further includes forming a third metal layer over the first metal layer prior to forming the second metal layer, wherein the third metal layer comprises a write bit-line landing pad, and a drain node of the first write pass-gate transistor of the first SRAM cell is electrically coupled to a drain node of the third write pass-gate transistor of the second SRAM cell through the write bit-line land pad.

In some embodiments, a method includes forming a first channel pattern over a substrate; forming a first gate pattern extending across the first channel pattern, and a second gate pattern extending across the first channel pattern; forming first source/drain patterns at opposite sides of the first gate pattern, and second source/drain patterns at opposite sides of the second gate pattern, wherein a first portion of the first channel pattern, the first gate pattern, and the first source/drain patterns form a first read pass-gate transistor of a first static random access memory (SRAM) cell, and a second portion of the first channel pattern, the second gate pattern, and the second source/drain patterns form a second read pass-gate transistor of a second SRAM cell; forming a read word-line over the substrate, wherein the read word-line is electrically coupled to the first gate pattern of the first read pass-gate transistor of the first SRAM cell, and from a top view, the first and second SRAM cells are arranged along a lengthwise direction of the read word-line; forming a read bit-line over the substrate, wherein one of the first source/drain patterns of the first read pass-gate transistor of the first SRAM cell is electrically coupled to one of the second source/drain patterns of the second read pass-gate transistor of the second SRAM cell through the read bit-line. In some embodiments, the method further includes forming a write bit-line and a write bit-line bar over the substrate, wherein the first and second SRAM cells share the write bit-line and the write bit-line bar. In some embodiments, the read bit-line is at a different level height than the write bit-line and the write bit-line bar. In some embodiments, from the top view, the read bit-line, the write bit-line, and the write bit-line bar extend in parallel with each other, and the read bit-line is situated between the write bit-line and the write bit-line bar. In some embodiments, the method further includes forming a third gate pattern extending across the first channel pattern; forming a gate end dielectric line at a longitudinal end of the third gate pattern, wherein form the top view, the gate end dielectric line extend along a boundary of the first and second SRAM cells in a lengthwise direction of the first channel pattern. In some embodiments, the semiconductor structure includes forming a second channel pattern over the substrate; forming third source/drain patterns on the second channel pattern; forming a third gate pattern extending across the first and second channel patterns, wherein a portion of the second channel pattern, the third gate pattern, and the third source/drain patterns form a write pull-up transistor of the first SRAM cell; forming a dielectric gate cutting through the second channel pattern.

In some embodiments, the semiconductor structure includes a substrate, a first static random access memory (SRAM) cell, a second SRAM cell, and a read bit-lin. The first SRAM cell is cell on the substrate. The first SRAM cell includes a first read pass-gate transistor. The second SRAM cell is over the substrate. The second SRAM cell includes a second read pass-gate transistor. The first read pass-gate transistor of the first SRAM cell and the second read pass-gate transistor of the second SRAM cell share a same channel layer. The read bit-line is over the substrate. The first read pass-gate transistor of the first SRAM cell is electrically coupled to the second read pass-gate transistor of the second SRAM cell through the read bit-line. In some embodiments, the first SRAM cell further comprises a first read pull-down transistor, the second SRAM cell further comprises a second read pull-down transistor, and the first and second read pull-down transistors share the same channel layer. In some embodiments, the semiconductor structure further includes a write bit-line over the substrate; a write bit-line bar over the substrate, the write bit-line bar being at a same level height as the write bit-line, wherein the first and second SRAM cells share the write bit-line and the write bit-line bar. In some embodiments, the semiconductor structure further includes a first read word-line over the substrate, wherein the first read word-line is electrically coupled to the first read pass-gate transistor of the first SRAM cell; a second read word-line extending in parallel with the first read word-line at a same level height as the first read word-line, wherein the second read word-line is electrically coupled to the second read pass-gate transistor of the second SRAM cell, and from a top view, the first and second SRAM cells are arranged along a lengthwise direction of the first read word-line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first static random access memory (SRAM) cell over a semiconductive substrate, the first SRAM cell comprising a first write port and a first read port;
forming a second SRAM cell over the semiconductive substrate and adjacent to the first SRAM cell, the second SRAM cell comprising a second write port and a second read port;
forming a first metal layer over the semiconductive substrate, the first metal layer comprising a read bit-line, wherein the first and second SRAM cells share the read bit-line; and
forming a second metal layer over the first metal layer, the second metal layer comprising a write bit-line and a write bit-line bar, wherein the first and second SRAM cells share the write bit-line and the write bit-line bar.

2. The method of claim 1, further comprising:
forming a third metal layer over the first metal layer prior to forming the second metal layer, wherein the third metal layer comprises a first read word-line and a second read word-line, the first read word-line is electrically coupled to the first SRAM cell, and the second read word-line is electrically coupled to the second SRAM cell.

3. The method of claim 2, wherein from a top view, the first and second SRAM cells are arranged along a lengthwise direction of the first read word-line.

4. The method of claim 2, further comprising:
forming a fourth metal layer over the second metal layer, wherein the fourth metal layer comprises a first write word-line and a second write word-line, the first write word-line is electrically coupled to the first SRAM cell, and the second write word-line is electrically coupled to the second SRAM cell.

5. The method of claim 1, wherein the first write port of the first SRAM cell comprises first and second write pull-up transistors, first and second write pull-down transistors, and first and second write pass-gate transistors, and the first read port of the first SRAM cell comprises a first read pull-down transistor and a first read pass-gate transistor.

6. The method of claim 5, wherein the first and second write pull-down transistors and the first and second write pass-gate transistors of the first SRAM cell share a same channel pattern.

7. The method of claim 5, wherein the first and second write pull-up transistors of the first SRAM cell share a same channel pattern.

8. The method of claim 5, wherein the second read port of the second SRAM cell comprises a second read pull-down transistor and a second read pass-gate transistor, the first read pass-gate transistor and the first read pass-gate transistor of the first SRAM cell and the second read pass-gate transistor and the second read pass-gate transistor of the second SRAM cell share a same channel pattern.

9. The method of claim 5, wherein the second write port of the second SRAM cell comprises third and fourth second write pull-up transistors, third and fourth write pull-down transistors, and third and fourth write pass-gate transistors.

10. The method of claim 9, further comprising:
forming a third metal layer over the first metal layer prior to forming the second metal layer, wherein the third metal layer comprises a write bit-line landing pad, and a drain node of the first write pass-gate transistor of the first SRAM cell is electrically coupled to a drain node of the third write pass-gate transistor of the second SRAM cell through the write bit-line land pad.

11. A method, comprising:
forming a first channel pattern over a substrate;
forming a first gate pattern extending across the first channel pattern, and a second gate pattern extending across the first channel pattern;
forming first source/drain patterns at opposite sides of the first gate pattern, and second source/drain patterns at opposite sides of the second gate pattern, wherein a first portion of the first channel pattern, the first gate pattern, and the first source/drain patterns form a first read pass-gate transistor of a first static random access memory (SRAM) cell, and a second portion of the first channel pattern, the second gate pattern, and the second source/drain patterns form a second read pass-gate transistor of a second SRAM cell;
forming a read word-line over the substrate, wherein the read word-line is electrically coupled to the first gate pattern of the first read pass-gate transistor of the first SRAM cell, and from a top view, the first and second SRAM cells are arranged along a lengthwise direction of the read word-line; and
forming a read bit-line over the substrate, wherein one of the first source/drain patterns of the first read pass-gate transistor of the first SRAM cell is electrically coupled to one of the second source/drain patterns of the second read pass-gate transistor of the second SRAM cell through the read bit-line.

12. The method of claim 11, further comprising:
forming a write bit-line and a write bit-line bar over the substrate, wherein the first and second SRAM cells share the write bit-line and the write bit-line bar.

13. The method of claim 12, wherein the read bit-line is at a different level height than the write bit-line and the write bit-line bar.

14. The method of claim 12, wherein from the top view, the read bit-line, the write bit-line, and the write bit-line bar extend in parallel with each other, and the read bit-line is situated between the write bit-line and the write bit-line bar.

15. The method of claim 11, further comprising:
forming a third gate pattern extending across the first channel pattern; and
forming a gate end dielectric line at a longitudinal end of the third gate pattern, wherein form the top view, the gate end dielectric line extend along a boundary of the first and second SRAM cells in a lengthwise direction of the first channel pattern.

16. The method of claim 11, further comprising:
forming a second channel pattern over the substrate;
forming third source/drain patterns on the second channel pattern;
forming a third gate pattern extending across the first and second channel patterns, wherein a portion of the second channel pattern, the third gate pattern, and the third source/drain patterns form a write pull-up transistor of the first SRAM cell; and
forming a dielectric gate cutting through the second channel pattern.

17. A semiconductor structure, comprising:
a substrate;
a first static random access memory (SRAM) cell over the substrate, the first SRAM cell comprising a first read pass-gate transistor;
a second SRAM cell over the substrate, the second SRAM cell comprising a second read pass-gate transistor, wherein the first read pass-gate transistor of the first SRAM cell and the second read pass-gate transistor of the second SRAM cell share a same channel layer; and
a read bit-line over the substrate, wherein the first read pass-gate transistor of the first SRAM cell is electrically coupled to the second read pass-gate transistor of the second SRAM cell through the read bit-line.

18. The semiconductor structure of claim 17, wherein the first SRAM cell further comprises a first read pull-down transistor, the second SRAM cell further comprises a second read pull-down transistor, and the first and second read pull-down transistors share the same channel layer.

19. The semiconductor structure of claim 17, further comprising:
a write bit-line over the substrate; and
a write bit-line bar over the substrate, the write bit-line bar being at a same level height as the write bit-line, wherein the first and second SRAM cells share the write bit-line and the write bit-line bar.

20. The semiconductor structure of claim 17, further comprising:
a first read word-line over the substrate, wherein the first read word-line is electrically coupled to the first read pass-gate transistor of the first SRAM cell; and
a second read word-line extending in parallel with the first read word-line at a same level height as the first read word-line, wherein the second read word-line is electrically coupled to the second read pass-gate transistor of the second SRAM cell, and from a top view, the first and second SRAM cells are arranged along a lengthwise direction of the first read word-line.
